(19) United States
(12) Patent Application Publication
(10) Pub. No.: US 2016/0103171 A1
(43) Pub. Date: Apr. 14, 2016

(54) Method for Estimating Life of Organic EL Element, Method for Producing Life Estimation Device, and Light-Emitting Device

(71) Applicant: CHEMICAL MATERIALS EVALUATION AND RESEARCH BASE, Ibaraki (KR)

(72) Inventors: Tetsuo Tsutsui, Tsukuba-shi, Ibaraki (JP); Kazunori Sugimoto, Tsukuba-shi, Ibaraki (JP); Toshihiro Yoshioka, Tsukuba-shi, Ibaraki (JP); Satoshi Miyaguchi, Tsukuba-shi, Ibaraki (JP)

(73) Assignee: Chemical materials Evaluation and REsearch BAse, Tsukuba-shi, Ibaraki (JP)

(21) Appl. No.: 14/786,489

(22) PCT Filed: Nov. 28, 2014
(86) PCT No.: PCT/JP2014/081580

§ 371 Date: Oct. 22, 2015

(30) Foreign Application Priority Data
Nov. 29, 2013 (JP) 2013-247990
May 30, 2014 (JP) 2014-112137

(51) Int. Cl. G01R 31/26; H01L 51/52; G01K 7/00; H01L 51/56

(52) U.S. Cl. CPC G01R 31/2642; G01R 31/2635; H01L 51/56; H01L 51/52; G01K 7/00

(57) ABSTRACT

A method for estimating a lifetime of an organic EL element comprising a pair of electrodes and an organic layer, comprises: a step of acquiring degradation data of characteristics of the element when a current density applied to the element and/or an atmosphere temperature of the element are/is changed; a step of calculating a fitting function of the degradation data and extracting a degradation parameter characterizing a degradation in the characteristics at the applied current density and/or the atmosphere temperature from the fitting function; a step of calculating a temperature dependence of the degradation parameter based on a temperature rise value of the organic layer upon light emission at the applied current density and/or the atmosphere temperature and setting a lifetime estimation formula of the element; and a step of estimating the lifetime of the organic EL element based on the lifetime estimation formula.

### TECHNICAL FIELD

The present invention relates to a method for estimating a lifetime of an organic EL element, a method for producing a lifetime estimation device, and a light-emitting device.

### BACKGROUND ART

When an organic EL element is used as, for example, a light source for illumination, the organic EL element needs to have a lifetime of about 40,000 hours or more in a standard condition (for example, luminance of about 3,000 to 5,000 cd/m²). On the other hand, in a lifetime test of the organic EL element, it is impractical to perform a measurement for a long time such as 40,000 hours, and it is usual to measure the lifetime in an acceleration condition in which the degradation of the organic EL element is accelerated by, for example, greatly increasing the luminance.

When the lifetime test is performed in such an acceleration condition, it is important to accurately estimate the lifetime in the standard condition from the lifetime in the acceleration condition. In the past, as a method for estimating a lifetime of an organic EL element, a method for fitting a degradation curve of an organic EL element with a function of power of an applied current density (see Non Patent Literatures 2 and 3), a method for fitting with a function of ambient temperature when driving an organic EL element (see Non Patent Literature 1), or the like has been used.

Also, the organic EL element needs to suppress the degradation of the organic EL element associated with use for, in particular, a light source of illumination, a display, or the like. Since the degradation of the organic EL element is considered to have a correlation with a temperature of an organic layer constituting the organic EL element, it is important to accurately measure the temperature of the organic layer so as to suppress the degradation of the organic EL element.

In the past, a technique for measuring a temperature of an organic layer by using an optical method such as Raman spectroscopy is known, but there are problems in terms of measurement accuracy or convenience. In this regard, Patent Literature 1 discloses a method that previously measures current-voltage-temperature characteristics of an organic EL element by applying a voltage signal or a current signal of a pulse waveform to the organic EL element at a plurality of different atmosphere temperatures and calculating an internal temperature of the organic EL element based on the current-voltage-temperature characteristics.

Also, Non Patent Literature 1 discloses a method that previously measures voltage-temperature characteristics of an organic EL element by applying a current signal to the organic EL element at a plurality of different atmosphere temperatures by using a constant low current signal and calculating an internal temperature of the organic EL element based on the voltage-temperature characteristics.

### CITATION LIST

### Patent Literature

Patent Literature 1: JP 2005-43143 A

### Non Patent Literature

Non Patent Literature 1: “Commercialization of World's First all-phosphorescent OLED Product for Lighting Application”, SID2012 DIGEST, 605-609
Non Patent Literature 2: “Physical mechanism responsible for the stretched exponential decay behavior of aging organic light-emitting diodes”, Applied Physics Letters 87, 213502 (2005)
Non Patent Literature 3: “Study on scalable Coulombic degradation for estimating the lifetime of organic light-emitting devices”, Journal of Physics D: Applied Physics, 44, 155103(2011)
Non Patent Literature 4: “Transient thermal characterization of organic light-emitting diodes”, Semiconductor Science and Technology, 27, 105011 (2012)

### SUMMARY OF INVENTION

### Technical Problem

However, in the above-described conventional lifetime estimating method, in particular, when lifetime test data by a high current density condition is used, there is a risk that the lifetime of the organic EL element cannot be accurately estimated.

An object of the present invention is to provide a method for estimating a lifetime of an organic EL element, a method for producing a lifetime estimation device, and a light-emitting device, which are capable of accurately estimating the lifetime of the organic EL element.

Also, according to examination conducted by the inventors of the present invention, it has been found that since the current-voltage-temperature characteristics were changed according to the degradation of the organic EL element, the accuracy of the calculated temperature were not always high when the temperature of the degraded organic EL element was calculated based on the current-voltage-temperature characteristics of the organic EL element previously measured by the method disclosed in Patent Literature 1.

Another object of the present invention is to provide a method for acquiring a temperature of an organic layer of an organic EL element, which is capable of measuring the temperature of the organic layer of the organic EL element with high accuracy.

### Solution to Problem

A method for estimating a lifetime of an organic EL element according to the present invention is a method for estimating a lifetime of an organic EL element comprising a pair of electrodes and an organic layer disposed between the pair of electrodes, the method comprising: a data acquiring step of acquiring degradation data of characteristics of the organic EL element when a current density applied to the organic EL element and/or an atmosphere temperature (ambient temperature) of the organic EL element are/is changed; a parameter extracting step of calculating a fitting function of the degradation data and extracting a degradation parameter characterizing a degradation in the characteristics at the applied current density and/or the atmosphere temperature (ambient temperature) from the fitting function; an estimation formula setting step of calculating a temperature dependence of the degradation parameter based on a temperature rise value of the organic layer upon light emission at the applied current density and/or the atmosphere temperature (ambient temperature) and setting a lifetime estimation formula of the organic EL element; and a lifetime estimating step of estimating the lifetime of the organic EL element based on the lifetime estimation formula.

In the method for estimating the lifetime of the organic EL element according to the present invention, the degradation parameter is extracted from the fitting function of the degradation data of the characteristics of the organic EL element, the temperature dependence of the degradation parameter is calculated by using the temperature rise value at the time of the emission of the organic layer, and the lifetime estimation formula of the organic EL element is set. That is, in the method for estimating the lifetime of the organic EL element, since the lifetime estimation formula is a formula considering the temperature rise value at the time of the emission of the organic layer, the lifetime of the organic EL element is estimated considering the self heat generation of the organic layer by the current application affecting the lifetime of the organic EL element. Therefore, in the method for estimating the lifetime of the organic EL element according to the present invention, the lifetime of the organic EL element can be more accurately estimated as compared to the conventional lifetime estimating method. Furthermore, even when the current density applied to the organic EL element is large (that is, the self heat generation of the organic layer is large), it is an excellent lifetime estimating method capable of accurately estimating the lifetime of the organic EL element.

It is preferable that the degradation parameter is a coefficient of a function characterizing the degradation of emission intensity being luminance, luminous flux, radiant flux, or the number of photons of the organic EL element, luminous efficiency representing luminous flux per unit input power, external quantum efficiency representing the number of photons taken out per unit current, or a driving voltage being a threshold value or a constant current in the fitting function. In this case, the lifetime of the organic EL element can be estimated based on the simply measured characteristics.

It is preferable that, in the estimation formula setting step, the degradation parameter is corrected based on the temperature dependence, a dependence due to another factor of the degradation parameter is derived, and the lifetime estimation formula including a product of a term representing the temperature dependence and a term representing the dependence due to the other factors is set. In this case, since the lifetime estimation formula is a formula considering the other factors as well as the temperature rise value of the organic layer, the lifetime of the organic EL element can be more accurately measured.

It is preferable that the other factor is the applied current density, an applied voltage, or input power, with respect to the organic EL element. In this case, since the lifetime estimation formula is a formula considering the factors greatly affecting the lifetime of the organic EL element, the lifetime of the organic EL element can be more accurately measured.

It is preferable that the temperature rise value is a temperature rise value acquired by measurement of current-voltage characteristics of the organic EL element, measurement of transient characteristics of the luminous intensity, or Raman spectroscopic measurement of the organic layer. In this case, since a more accurate temperature rise value of the organic layer is used, the lifetime of the organic EL element can be more accurately measured.

It is preferable that the temperature rise value is a temperature rise value acquired by a method comprising: a first step of, at a plurality of atmosphere temperatures, maintaining the organic EL element for a predetermined time under each atmosphere temperature and acquiring initial data about a correlation between the temperature of the organic layer and the voltage by measuring a voltage between the electrodes when a pulse current is applied to the organic EL element; a second step of driving and stopping the organic EL element; a third step of, after the second step, maintaining the organic EL element for a predetermined time under a predetermined atmosphere temperature (T₁) and measuring a voltage (V₁) when the same pulse current as the pulse current in the first step is applied to the organic EL element; a fourth step of correcting the initial data based on the temperature (T₁) and the voltage (V₁) acquired in the third step and acquiring correction data about the correlation between the temperature of the organic layer and the voltage; and a fifth step of measuring a voltage (V₂) between the electrodes when the same pulse current as the pulse current in the first step is applied to the organic EL element and acquiring a temperature (T₂) corresponding to the voltage (V₂) based on the correction data.

In this method, in the third step, the voltage between the electrodes is measured when the pulse current is applied to the driven organic EL element, and in the fourth step, the correction data is acquired by correcting the initial data about the correlation between the previously measured temperature and voltage of the organic layer based on the temperature and the voltage of the organic layer measured in the third step. Therefore, in this method, the temperature of the organic EL element is measured based on the correlation between the temperature and the inter-electrode voltage of the organic layer in the degraded organic EL element. Therefore, the temperature of the organic layer can also be measured with high accuracy with respect to the organic EL element degraded along with the driving.

It is preferable that the above method further comprises, before the first step, a step of driving the organic EL element at the same applied current value as the applied current value in the second step. In this case, the temperature of the organic layer can be measured with high accuracy with respect to the organic EL element in which the correlation between the temperature of the organic layer and the voltage is changed by the current application itself at the time of the driving.

It is preferable that the first step comprises a step of driving the organic EL element at the same applied current value as the applied current value in the second step before the pulse current is applied to the organic EL element, at all or part of the atmosphere temperatures of the plurality of atmosphere temperatures. In this case, the temperature of the organic layer can be measured with high accuracy with respect to the organic EL element in which the correlation between the temperature of the organic layer and the voltage is changed depending on the current application itself at the time of the driving and the temperature of the organic layer.

It is preferable that, in the data acquiring step, a degradation in the temperature is measured by acquiring the temperature rise value of the organic layer along with the degradation parameter, and in the estimation formula setting step, the lifetime estimation formula is set based on a degradation in the temperature rise value. In this case, since the lifetime estimation formula is a formula considering the degradation in the temperature of the organic layer, the lifetime of the organic EL element can be more accurately measured.

The fitting function of the degradation data can be the following Formula (1), (2), or (3):

$$\begin{matrix}[ Math . 1 ] & \\ L ( t ) = {L}_{0} \cdot \sum \{ {a}_{i} \cdot exp ( - \frac{t}{{τ}_{i}} ) \} \\ ( where , \sum {a}_{i} = 1 ) & ( 1 ) \\ [ Math . 2 ] & \\ L ( t ) = {L}_{0} \cdot exp \{ - {( \frac{t}{τ} )}^{b} \} & ( 2 ) \\ [ Math . 3 ] & \\ L ( t ) = \frac{{L}_{0}}{{( 1 + ct )}^{d}} \\ ( where , 1 < d < 2 ) & ( 3 )\end{matrix}$$

[in Formulas (1), (2), and (3), L(t) represents emission intensity after time t from the beginning of a lifetime test of the organic EL element, L₀ represents emission intensity at the beginning of the lifetime test of the organic EL element, and aᵢ, b, c, d, τᵢ, and τ represent degradation parameters.]

A lifetime estimation device of an organic EL element according to the present invention is a lifetime estimation device of an organic EL element for estimating the lifetime of the organic EL element, the lifetime estimation device comprising: a lifetime estimation unit estimating the lifetime of the organic EL element by using the above method for estimating the lifetime of the organic EL element; and a temperature acquisition unit that acquires the temperature rise value. According to the lifetime estimation device of the present invention, the lifetime of the organic EL element can be more accurately estimated as compared to the conventional lifetime estimation device.

A method for manufacturing an organic EL element according to the present invention, comprises a step of acquiring an organic EL element by disposing an organic layer between a pair of electrodes; a step of estimating a lifetime of the organic EL element by using the above method for estimating the lifetime of the organic EL element; and a step of comparing the estimated lifetime with a reference value of the lifetime and determining whether the organic EL element has the acceptable quality or not. According to the manufacturing method of the present invention, it is possible to produce a good-quality organic EL element whose lifetime is accurately estimated.

A light-emitting device according to the present invention comprises: an organic EL element; a lifetime estimation unit estimating a lifetime of the organic EL element by using the above method for estimating the lifetime of the organic EL element; and a temperature acquisition unit acquiring the temperature rise value. According to the light-emitting device of the present invention, the lifetime of the organic EL element can be more accurately estimated and determined as compared to the conventional light-emitting device.

The temperature acquisition unit in the lifetime estimation device and the light-emitting device may be configured by a temperature acquisition system comprising: a temperature control unit controlling the atmosphere temperature of the organic EL element; a pulse current source applying a pulse current to the organic EL element; a voltage measurement unit measuring a voltage between the pair of electrodes when the pulse current is applied to the organic EL element; and a data processing unit processing the data about the correlation between the temperature of the organic layer and the voltage.

The light-emitting device may further comprise a lifetime determination unit that determines the lifetime of the organic EL element by comparing the estimated lifetime and a reference value of the lifetime.

### Advantageous Effects of Invention

According to the present invention, it is possible to provide a method for estimating a lifetime of an organic EL element, a method for producing a lifetime estimation device, and a light-emitting device, which are capable of accurately estimating the lifetime of the organic EL element. Furthermore, even when the current density applied to the organic EL element is large (that is, the self heat generation of the organic layer is large), it is possible to provide a method for estimating a lifetime of an organic EL element, a method for producing a lifetime estimation device, and a light-emitting device, which are capable of accurately estimating the lifetime of the organic EL element.

### BRIEF DESCRIPTION OF DRAWINGS

FIG. 1 shows elements of a lifetime estimation device of an organic EL element according to an embodiment of the present invention.

FIG. 2 is a flowchart showing a method for estimating a lifetime of an organic EL element according to an embodiment of the present invention.

FIG. 3 is a graph showing an example of a degradation curve of an organic EL element.

FIG. 4 is a graph showing an example of an applied current density dependence of a degradation curve of an organic EL element.

FIG. 5 is a graph showing an example of a relationship between an applied current density and a temperature of an organic layer.

FIG. 6 is a graph showing an example of a temperature dependence of a degradation parameter.

FIG. 7 is a graph showing an example of an applied current density dependence of a degradation parameter in a case where a temperature dependence is excluded from the degradation parameter.

FIG. 8 is a graph showing an example of an applied current density dependence of a degradation parameter in each ambient temperature.

FIG. 9 is a graph showing an example of a relationship between an initial luminance and a lifetime test time.

FIG. 10 is a graph showing another example of an applied current density dependence of a degradation curve of an organic EL element.

FIG. 11 is a graph showing an example of a degradation curve of an organic EL element with respect to normalized elapsed time in various acceleration conditions.

FIG. 12 is a graph showing another example of a temperature dependence of a degradation parameter.

FIG. 13 is a graph showing another example of an applied current density dependence of a degradation parameter in a case where a temperature dependence is excluded from the degradation parameter.

FIG. 14 is a graph showing another example of an applied current density dependence of a degradation parameter in each ambient temperature.

FIG. 15 shows an example of a table which a lifetime estimation device of an organic EL element or a light-emitting device has.

FIG. 16 is a graph showing an example of an applied current density dependence of a degradation parameter in the case of using a conventional lifetime estimating method.

FIG. 17 shows elements of a temperature acquisition system according to an embodiment of the present invention.

FIG. 18 is a graph showing an example of a relationship between an initial calibration curve and a corrected calibration curve.

FIG. 19 is a graph showing a relationship between an initial calibration curve and a corrected calibration curve according to an embodiment.

FIG. 20 is a graph showing a change in a calibration curve due to a current application according to an embodiment.

FIG. 21 includes graphs showing a correlation between a temperature of an organic layer and an inter-electrode voltage according to an embodiment.

FIG. 22 includes graphs showing a relationship between an applied current value and a change in a calibration curve according to an embodiment.

### DESCRIPTION OF EMBODIMENTS

Hereinafter, embodiments of a method for estimating a lifetime of an organic EL element, a lifetime estimation device of an organic EL element, a method for producing of an organic EL element, and a light-emitting device, according to the present invention, are described in detail with reference to the drawings.

A method for estimating a lifetime of an organic EL element according to the present embodiment is a method for estimating a lifetime of an organic EL element including a pair of electrodes and an organic layer disposed between the pair of electrodes. The method for estimating the lifetime of the organic EL element includes: a data acquiring step of acquiring degradation data of characteristics of the organic EL element when a current density applied to the organic EL element and/or an atmosphere temperature (ambient temperature) of the organic EL element are/is changed; a parameter extracting step of calculating a fitting function of degradation data and extracting a degradation parameter characterizing a degradation in the characteristics at the applied current density and/or the atmosphere temperature (ambient temperature) from the fitting function; an estimation formula setting step of calculating a temperature dependence of the degradation parameter by using a temperature rise value upon light emission of the organic layer at the applied current density and/or the atmosphere temperature (ambient temperature) and setting a lifetime estimation formula of the organic EL element; and a lifetime estimating step of estimating the lifetime of the organic EL element by using the lifetime estimation formula.

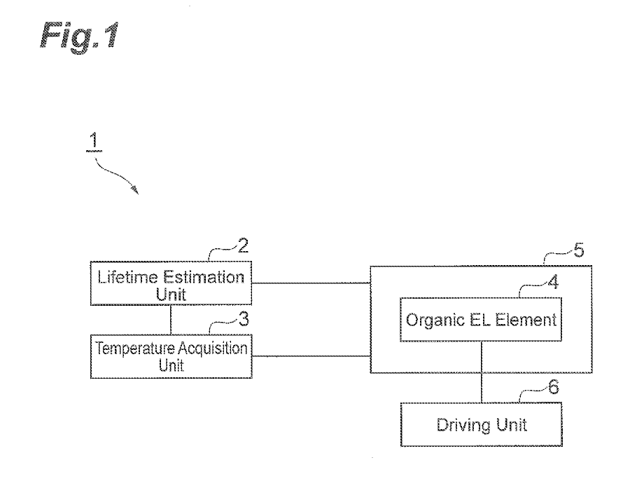

FIG. 1 shows elements of a lifetime estimation device of an organic EL element according to the present embodiment. As shown in FIG. 1, the lifetime estimation device 1 includes, for example, a lifetime estimation unit 2, a temperature acquisition unit 3, an installation unit 5 that installs an organic EL element 4, and a driving unit 6 that drives the organic EL element 4.

The configuration of the organic EL element 4 is not particularly limited as long as the organic EL element 4 includes a pair of electrodes and an organic layer disposed between the pair of electrodes (the organic EL element 4 includes two electrodes and an organic layer interposed between the two electrodes and emits light by applying current to the organic EL element). As the configuration of the organic EL element 4, a configuration of a substrate/anode/hole injection layer/hole transport layer/emission layer/hole blocking layer/electron transport layer/electron injection layer/cathode can be exemplified. In the case of this example, for example, each of the hole injection layer, the hole transport layer, the emission layer, the hole blocking layer, the electron transport layer, and the electron injection layer can be configured by an organic layer.

The installation unit 5 is configured by, for example, a thermostatic bath capable of maintaining a temperature of an atmosphere where the organic EL element 4 is installed (hereinafter, referred to as “atmosphere temperature” or “ambient temperature”) at a predetermined temperature. The driving unit 6 drives the organic EL element 4 by applying a predetermined DC current to the organic EL element 4.

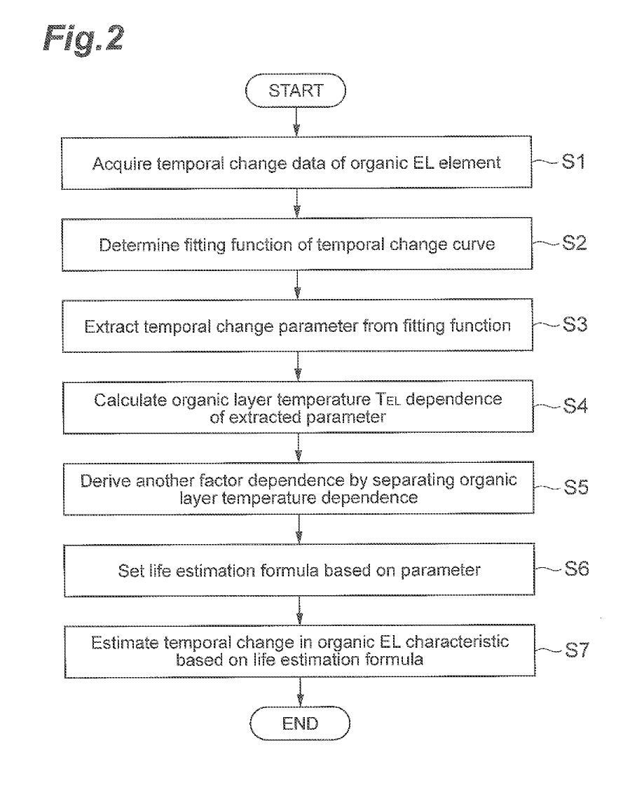

The lifetime estimation unit 2 estimates the lifetime of the organic EL element 4 by a method for estimating the lifetime of the organic EL element, which includes a data acquiring step, a parameter extracting step, an estimation formula setting step, and a lifetime estimating step. FIG. 2 is a flowchart showing an example of the method for estimating the lifetime of the organic EL element according to the present embodiment.

In the data acquiring step, a lifetime test is performed by changing a current density applied to the organic EL element and/or an ambient temperature of the organic EL element and measuring a degradation in characteristics of the organic EL element at each applied current density and/or each ambient temperature. The “characteristics of the organic EL element” in the present embodiment means emission intensity such as luminance, luminous flux, radiant flux, or the number of photons.

In the present embodiment, the lifetime test can be performed by applying a current density J₀, at which an initial luminance of the organic EL element has a predetermined value (for example, 1,000 to 5,000 cd/m²), to the organic EL element and measuring the emission intensity (for example, luminance) of the organic EL element. As described above, in the data acquiring step, the degradation data of the characteristics, such as the emission intensity of the organic EL element, is acquired (S1 in FIG. 2).

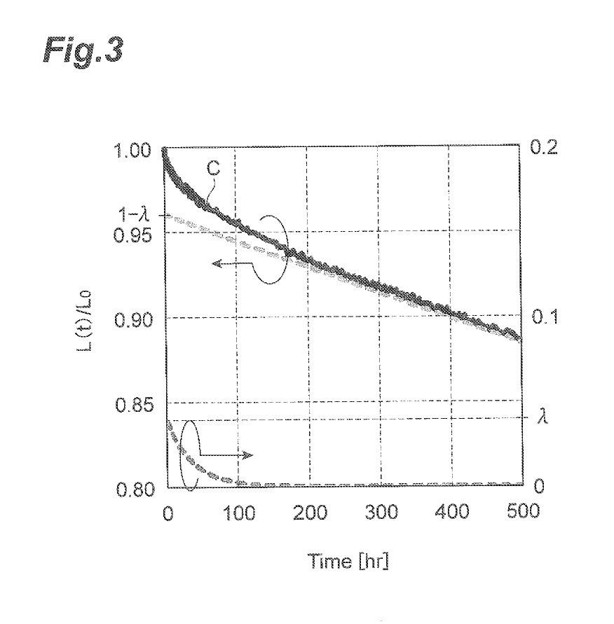

Subsequently, the lifetime estimation unit 2 performs the parameter extracting step. From the result of the lifetime test in the data acquiring step, it can be seen that the emission intensity of the organic EL element decays with the elapse of time like a degradation curve C, for example, as shown in FIG. 3. A vertical axis (a left vertical axis) of the degradation curve C represents a ratio L(t)/L₀ of the emission intensity L(t) after time t with respect to the emission intensity L₀ at the beginning of the lifetime test.

The degradation curve C can be fit with a fitting function expressed by, for example, the following Formula (1), (2), or (3) (S2 in FIG. 2).

$$\begin{matrix}[ Math . 4 ] & \\ L ( t ) = {L}_{0} \cdot \sum \{ {a}_{i} \cdot exp ( - \frac{t}{{τ}_{i}} ) \} \\ ( where , \sum {a}_{i} = 1 ) & ( 1 ) \\ [ Math . 5 ] & \\ L ( t ) = {L}_{0} \cdot exp \{ - {( \frac{t}{τ} )}^{b} \} & ( 2 ) \\ [ Math . 6 ] & \\ L ( t ) = \frac{{L}_{0}}{{( 1 + ct )}^{d}} \\ ( where , 1 < d < 2 ) & ( 3 )\end{matrix}$$

[In Formulas (1), (2), and (3), L(t) represents the emission intensity after time t from the beginning of the lifetime test of the organic EL element, L₀ represents the emission intensity at the beginning of the lifetime test of the organic EL element, and aᵢ, b, c, d, τᵢ, and τ represent degradation parameters.]

In the case of using Formula (1), a major one (a greatly contributing one) from aᵢ and τᵢ can be extracted as a degradation parameter. The degradation parameter can be one or two or more.

In the case of using Formula (1), Formula (1) can be used after being simplified by adding an initial decay item as shown in Formula (4) below.

$$\begin{matrix}[ Math . 7 ] & \\ L ( t ) = {L}_{0} \cdot \{ λ \cdot f ( 1 ) + ( 1 - λ ) \cdot exp ( - \frac{t}{{τ}_{2}} ) \} \\ ( where , λ < < 1 , f ( 0 ) = 1 ) & ( 4 )\end{matrix}$$

In Formula (4), L(t) represents the emission intensity after time t from the beginning of the lifetime test of the organic EL element, L₀ represents the emission intensity at the beginning of the lifetime test of the organic EL element, λ represents a number from 0 to 1, τ₂ represents the degradation parameter, and f(t) represents a function showing the initial decay of the emission intensity. In this case, in the fitting function expressed by Formula (4), the parameter that dominates the lifetime can be τ₂.

In the present embodiment, the degradation curve C can be fit with a fitting function expressed by, for example, the following formula (5) that embodies Formula (4). In Formula (5), λ, τ₁, and τ₂ represent the degradation parameters.

$$\begin{matrix}[ Math . 8 ] & \\ L ( t ) = {L}_{0} \cdot \{ λ \cdot exp ( - \frac{t}{{τ}_{1}} ) + ( 1 - λ ) \cdot exp ( - \frac{t}{{τ}_{2}} ) \} & ( 5 )\end{matrix}$$

FIG. 3 shows an example of the degradation of the first term (a dashed line of a lower side whose intercept value is λ) and the second term (a dashed line of an upper side whose intercept value is 1−λ) in Formula (5). The value of the first term is shown on a right vertical axis, and the value of the second term is shown on a left vertical axis. As is obvious from FIG. 3, the value of the first term is substantially zero after the elapse of about 100 hours. In other words, it is obvious that, sometime after the beginning of the lifetime test, the contribution of the second term in Formula (5) is dominant in the degradation curve C of the organic EL element and τ₂ characterizes the degradation in the characteristics of the organic EL element.

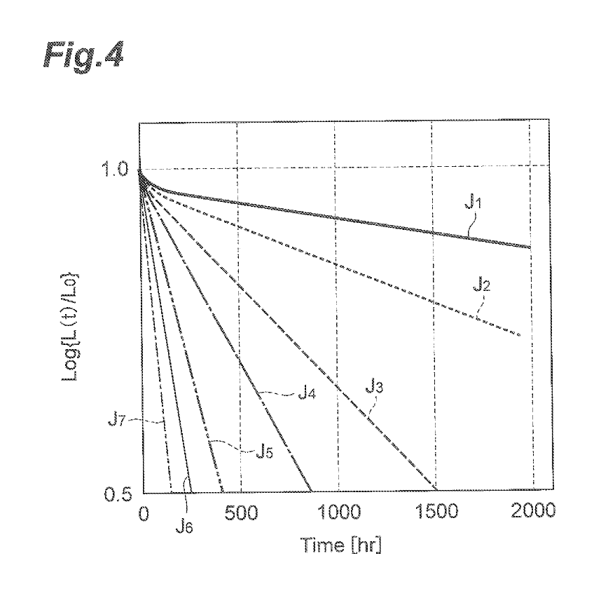

FIG. 4 shows an example of the degradation curve of the organic EL element at each current density when a current density applied to the organic EL element is changed at a certain ambient temperature. The degradation curves J₁, J₂, . . . J₇ shown in FIG. 4 are degradation curves when the current density J₀×n, which is n times the current density J₀ having a predetermined initial luminance, is applied. For example, a correspondence of the degradation curves J₁, J₂, . . . J₇ and n can be as follows.

J₁: n=0.5, J₂: n=1, J₃: n=2, J₄: n=3, J₅: n=5, J₆: n=7, J₇: n=10

In a single logarithmic plot in FIG. 4, all the degradation curves J₁, J₂, . . . J₇ become straight lines sometime (about 100 hours) after the beginning of the lifetime test. From this fact, as described above, after the elapse of a predetermined time, it is obvious that the contribution of the second term in Formula (5) is dominant in the degradation curves of the organic EL element and τ₂ characterizes the degradation in the characteristics of the organic EL element.

As described above, in the parameter extracting step, the fitting function of the degradation data acquired in the data acquiring step is calculated, and the degradation parameter characterizing the degradation in the characteristics of the organic EL element is extracted from the fitting function. In the present embodiment, the emission intensity (for example, luminance) of the organic EL element is measured and a coefficient of the emission intensity (for example, luminance) in the fitting function is used as the degradation parameter, but the emission intensity being the luminous flux, the radiant flux, or the number of photons of the organic EL element, the luminous efficiency representing the luminous flux per unit input power, the external quantum efficiency representing the number of photons taken out per unit current, or the driving voltage being a threshold value or a constant current may be measured and a coefficient of the luminous intensity being the luminous flux, the radiant flux, or the number of photons, or the driving voltage being the threshold value or the constant current in the fitting function may be used as the degradation parameter. The threshold value is, for example, a threshold value set as a value that is a constant multiple of an initial driving voltage.

Subsequently, the lifetime estimation unit 2 performs the estimation formula setting step. In order to calculate the lifetime estimation formula, a temperature rise value of the organic layer of the organic EL element is measured beforehand. Here, the “temperature rise value of the organic layer” may be a temperature rise value of the entire organic layer included in the organic EL element or may be, for example, a temperature rise value of the emission layer. Then, an organic layer temperature T_{EL} is estimated from the calculated temperature rise value of the organic layer.

The measurement of the temperature rise value of the organic layer may be performed only at the beginning of the emission of the organic EL element (at the beginning of the lifetime test) or may be performed at predetermined intervals (for example, every ten hours) during the lifetime test. In a case where the measurement of the temperature rise value of the organic layer is performed only at the beginning of the emission of the organic EL element (at the beginning of the lifetime test), the temperature rise value acquired by the measurement may be used as the temperature rise value of the organic layer in all periods during the lifetime test. On the other hand, in a case where the measurement of the temperature rise value of the organic layer is performed at predetermined intervals during the lifetime test, the temperature rise value acquired by a certain measurement may be used as the temperature rise value of the organic layer until a next measurement is performed after the measurement is performed. In order to more accurately reflect the temperature rise value of the organic layer to the lifetime estimation, it is preferable to perform the measurement of the temperature rise value of the organic layer at predetermined intervals during the lifetime test.

For example, the temperature rise value of the organic layer can be calculated from the measurement of current-voltage characteristic (IV characteristic) of the organic EL layer. Specifically, the temperature of the organic EL element is maintained at a constant temperature in a thermostatic bath, and an inter-electrode voltage of the organic EL element at the time of applying the current pulse is measured by using a current pulse in which the temperature rise due to the driving is suppressed. By repeating the measurement while changing the temperature of the organic EL element (temperature of the thermostatic bath), the current-voltage characteristic dependent on the temperature can be acquired as a calibration curve. Subsequently, the voltage is measured by promptly applying the same current pulse as described above from such a state that the organic EL element is actually driven to emit light. By comparing the voltage at the time of the driving with the calibration curve, the temperature rise value of the organic layer at the time of the driving can be estimated.

Alternatively, the temperature rise value of the organic layer can be obtained by Raman spectroscopic measurement of the organic layer. Specifically, the temperature of the organic layer can be estimated by detecting Raman scattered light from a specific organic layer constituting the organic EL element and using an intensity ratio of stokes light to anti-stokes light. In addition, the temperature rise value of the organic layer at the time of the driving can be estimated as follows: maintaining the temperature of the organic EL element at a constant temperature in the thermostatic bath; measuring a wavelength shift or a peak width of the Raman scattered light; acquiring the wavelength shift or the peak width dependent on the temperature as the calibration curve by repeating the measurement while changing the temperature of the organic EL element (temperature of the thermostatic bath); detecting the Raman scattered light in such a state that the organic EL element is actually driven to emit light; and comparing the wavelength shift or the peak width at that time with the calibration curve.

Alternatively, the temperature rise value of the organic layer can be obtained by measuring transient characteristics of the luminous intensity of the organic EL element. Specifically, the temperature of the organic EL element is maintained at a constant temperature in the thermostatic bath, photoluminescence from a specific organic layer constituting the organic EL element is observed using pulsed excitation light, and then a time constant of the intensity decay is acquired. By repeating the measurement while changing the temperature of the organic EL element (temperature of the thermostatic bath), the time constant dependent on the temperature can be acquired as the calibration curve. Subsequently, the temperature rise value of the organic layer at the time of the driving can be estimated by measuring the time constant of the photoluminescence in such a state that the organic EL element is actually driven to emit light and comparing the time constant at that time with the calibration curve.

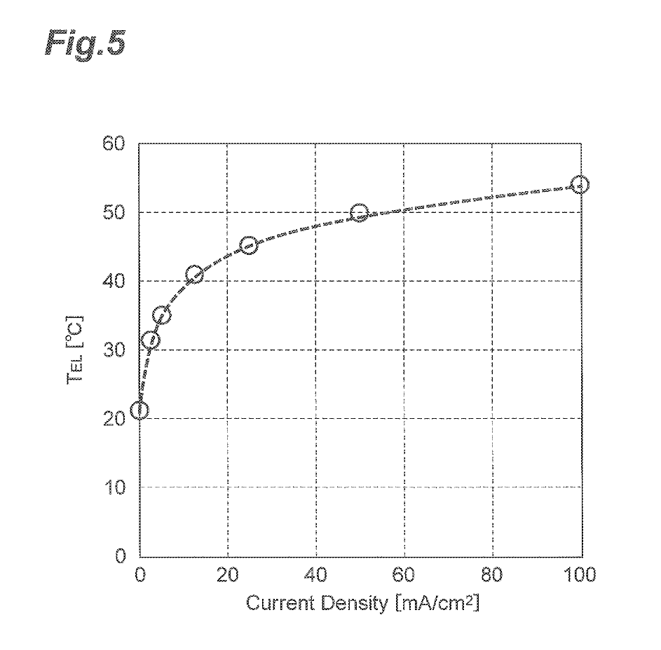

When the organic layer temperature T_{EL} estimated using the temperature rise value of the organic layer calculated from the IV characteristic measurement is plotted with respect to the current density applied to the organic EL element, for example, the plot shown in FIG. 5 is acquired. FIG. 5 shows the curve (dashed line) approximated based on these data.

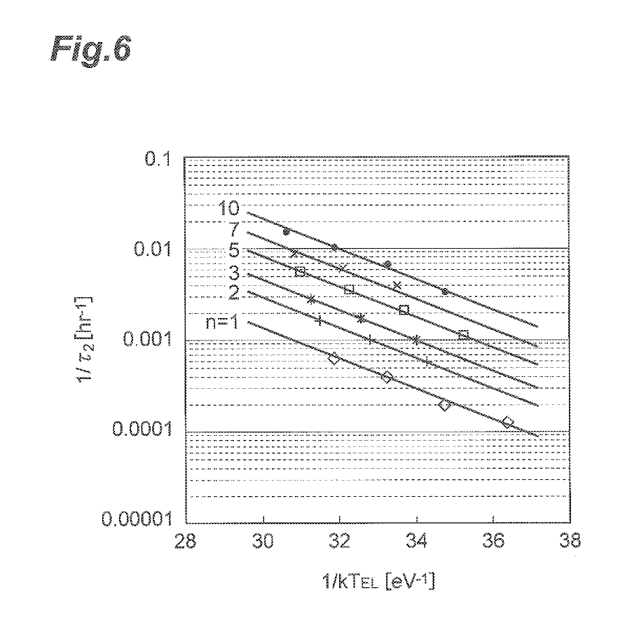

In order to know the organic layer temperature T_{EL} dependence of the degradation parameter τ₂ by using the organic layer temperature T_{EL} at each calculated current density, an Arrhenius plot (logarithmic plot of 1/τ₂ with respect to 1/kT_{EL}) is performed as shown in FIG. 6 (S4 in FIG. 2). k represents a Boltzmann constant. As can be seen from FIG. 6, 1/τ₂ shows a substantially constant slope with respect to 1/kT_{EL} in a single logarithmic plot, regardless of the magnitude of the current density applied to the organic EL element.

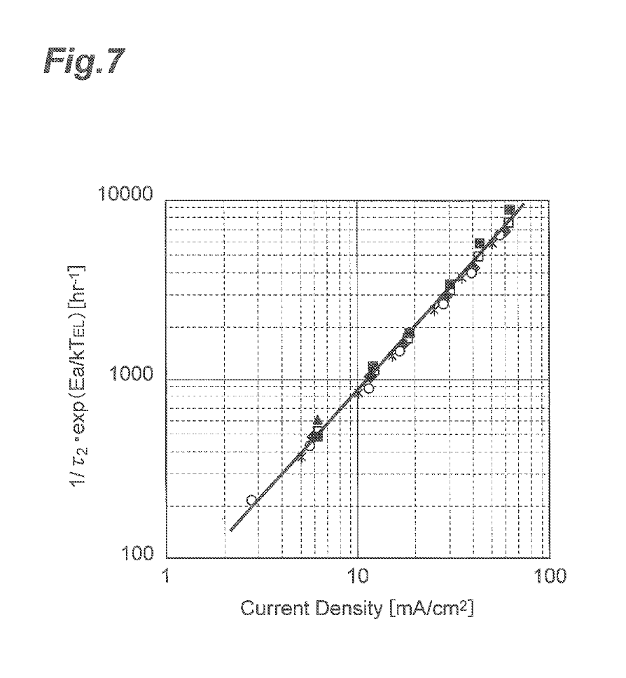

On the other hand, in order to exclude the organic layer temperature T_{EL} dependence of the degradation parameter τ₂ and know the dependence of the degradation parameter τ₂ with respect to the current density J applied to the organic EL element, a logarithmic plot of 1/τ₂·exp (Ea/kT_{EL}) is performed with respect to the current density J as shown in FIG. 7 (S5 in FIG. 2). As can be seen from FIG. 7, 1/τ₂·exp (Ea/kT_{EL}) shows a substantially constant slope with respect to the current density J in the logarithmic plot.

From FIGS. 6 and 7, it can be seen that τ₂ is expressed by the following Formula (6). A represents a positive number.

$$\begin{matrix}[ Math . 9 ] & \\ \frac{1}{{τ}_{2}} = A \cdot {J}^{β} \cdot exp ( - \frac{Ea}{{kT}_{EL}} ) & ( 6 )\end{matrix}$$

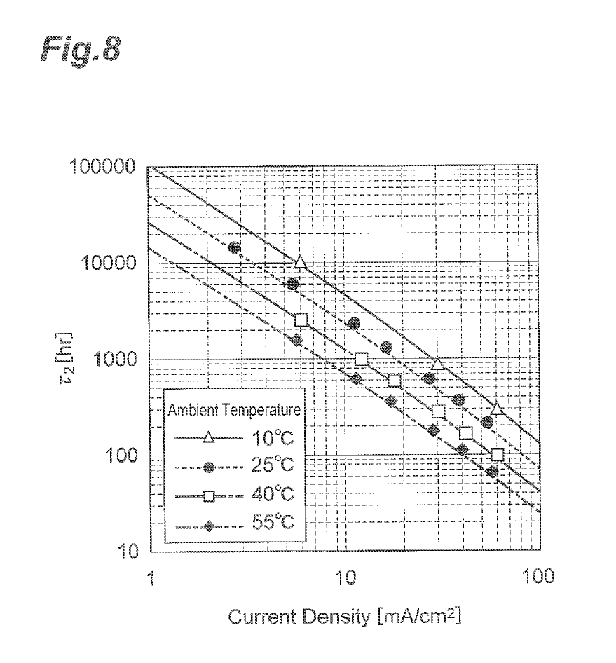

FIG. 8 shows the result obtained by plotting the degradation parameter τ₂ acquired from the lifetime test at each ambient temperature with respect to the current density. In addition, in FIG. 8, a relationship between the current density and the degradation parameter τ₂, which is calculated by Formula (6) at each ambient temperature, is indicated by a solid line, a dashed line, and the like. As is obvious from FIG. 8, it can be seen that the relationship between the applied current density and the degradation parameter τ₂, which is acquired by Formula (6) including the organic layer temperature T_{EL}, well reproduces the current density dependence of the degradation parameter τ₂ acquired from the lifetime test.

From the above, the fitting function of the degradation data of the organic EL element according to the present embodiment can be the following Formula (5) that embodies the following Formula (4) (S6 in FIG. 2). Here, τ₂ in Formulas (4) and (5) can be expressed by Formula (6) below.

$$\begin{matrix}[ Math . 10 ] & \\ L ( t ) = {L}_{0} \cdot \{ λ \cdot f ( t ) + ( 1 - λ ) \cdot exp ( - \frac{t}{{τ}_{2}} ) \} \\ ( where , λ < < 1 , f ( 0 ) = 1 ) & ( 4 ) \\ [ Math . 11 ] & \\ L ( t ) = {L}_{0} \cdot \{ λ \cdot exp ( - \frac{t}{{τ}_{1}} ) + ( 1 - λ ) \cdot exp ( - \frac{t}{{τ}_{2}} ) \} & ( 5 ) \\ [ Math . 12 ] & \\ \frac{1}{{τ}_{2}} = A \cdot {J}^{β} \cdot exp ( - \frac{Ea}{{kT}_{EL}} ) & ( 6 )\end{matrix}$$

As described above, in the estimation formula setting step, the lifetime estimation formula of the organic EL element is set by calculating the organic layer temperature dependence of the degradation parameter by using the temperature rise value at the time of the emission of the organic layer. In the above example, the lifetime estimation formula is set based on the dependence of the degradation parameter τ₂ on the current density applied to the organic EL element besides the organic layer temperature, but the lifetime estimation formula may be set based on the dependence of the degradation parameter τ₂ on the voltage applied to the organic EL element or the power input to the organic EL element.

Then, in the lifetime estimating step, the lifetime in the standard driving condition is estimated from the lifetime in the acceleration condition based on Formula (4) or (5) (S7 in FIG. 2).

As described above, the lifetime estimation unit 2 estimates the lifetime of the organic EL element 4. The lifetime estimation unit 2 may estimate the lifetime of the organic EL element 4 by performing the flow shown in FIG. 2 once, or may estimate the lifetime of the organic EL element 4 by repeating the flow shown in FIG. 2 twice or more.

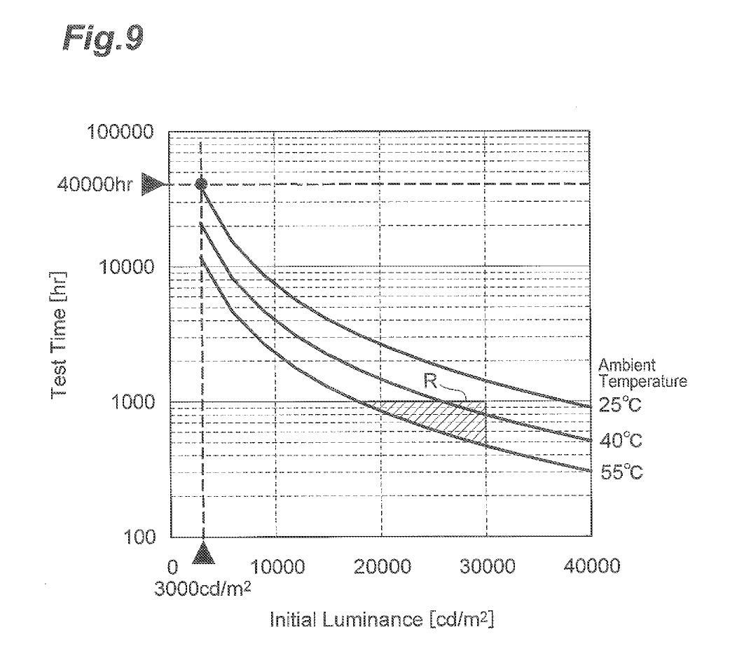

Also, according to the method for estimating the lifetime of the organic EL element, for example, as shown in FIG. 9, in the organic EL element having the lifetime of 40,000 hours at the ambient temperature of 25° C. and the initial luminance of 3,000 cd/m², when the lifetime is estimated within 1,000 hours in the acceleration condition of the ambient temperature of 55° C. or less and the initial luminance of 30,000 cd/m², it can be easily seen that the lifetime can be estimated within 1,000 hours if the acceleration condition is included in a region indicated by R. That is, according to the method for estimating the lifetime of the organic EL element, it is possible to accurately estimate the necessary acceleration condition.

As described above, in the method for estimating the lifetime of the organic EL element, the lifetime estimation formula is a formula considering the temperature of the organic layer at the time of the emission (the organic layer temperature T_{EL}). Therefore, the lifetime of the organic EL element can be estimated considering the self heat generation of the organic layer by the current application affecting the lifetime of the organic EL element. Therefore, in the method for estimating the lifetime of the organic EL element, the lifetime of the organic EL element can be more accurately estimated as compared to the conventional lifetime estimating method. Furthermore, even when the current density applied to the organic EL element is large (that is, the self heat generation of the organic layer is large), the lifetime of the organic EL element can be accurately estimated.

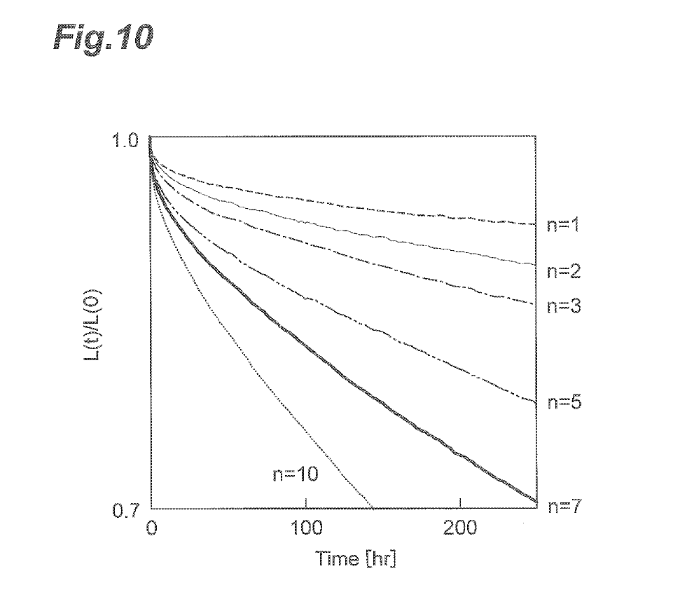

In the above embodiment, the lifetime estimation unit 2 fits the degradation curve by the fitting function expressed by Formula (1), (2), or (3) in the parameter extracting step, but the lifetime estimation unit 2 may fit the degradation curve of the organic EL element, for example, as shown in FIG. 10, by the fitting function expressed by Formula (7), (8), or (9) in the parameter extracting step. Formula (7) is an extension of Formula (4) along Formula (1).

$$\begin{matrix}[ Math . 13 ] & \\ L ( t ) = {L}_{0} \cdot [ γ \cdot g ( t ) + ( 1 - γ ) \cdot \sum \{ {a}_{i} \cdot exp ( - \frac{t}{{τ}_{i}} ) \} ] \\ ( where , \sum {a}_{i} = 1 ) & ( 7 ) \\ [ Math . 14 ] & \\ L ( t ) = {L}_{0} \cdot [ γ \cdot g ( t ) + ( 1 - γ ) \cdot exp \{ - {( \frac{t}{τ} )}^{b} \} ] & ( 8 ) \\ [ Math . 15 ] & \\ L ( t ) = {L}_{0} \cdot \{ γ \cdot g ( t ) + ( 1 - γ ) \cdot \frac{1}{{( 1 + ct )}^{d}} \} \\ ( where , 1 < d < 2 ) & ( 9 )\end{matrix}$$

In Formulas (7), (8), and (9), L(t), L₀, aᵢ, b, c, d, τᵢ, and τ have the same meanings as L(t), L₀, aᵢ, b, c, d, τᵢ, and τ in Formulas (1), (2), and (3). γ is a degradation parameter satisfying 0<γ<1. g(t) represents a function corresponding to an initial degradation of the organic EL element and is a function expressed by, for example, g(t)=exp(−t/τ′). In the case of using Formula (7), (8), or (9), a more accurate fitting is possible because the degradation curve is fit by the function considering the initial degradation of the organic EL element.

In the following, a detailed description is given with reference to the case of using Formula (8). For example, the organic EL element shows a degradation curve as shown in FIG. 10. Each of n=1, 2, 3, 5, 7, and 10 shows a degradation curve when a current density of J₀×n is applied to the organic EL element with respect to the applied current density J₀ being the reference.

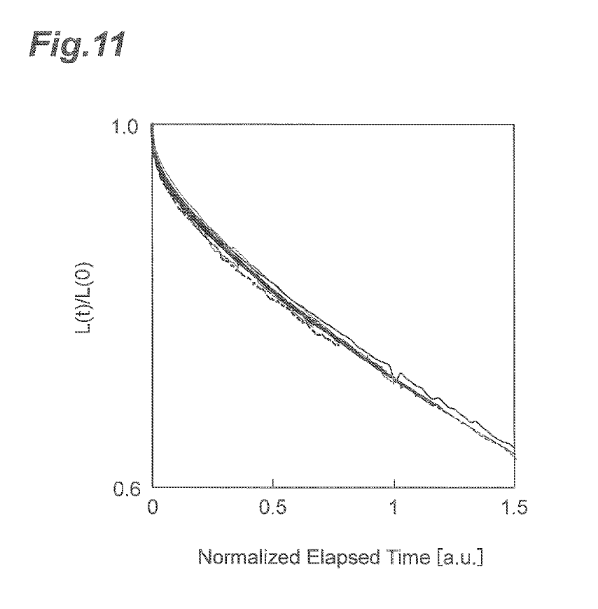

In this case, when the elapsed time (a horizontal axis in FIG. 10) is normalized, a degradation curve is as shown in FIG. 11. The normalization of the elapsed time is performed by dividing the elapsed time by a time being a constant decay rate (for example, L(t)/L(0)=0.7, etc.). As is obvious from FIG. 11, the degradation curves almost overlap one other with respect to the normalized elapsed time in all acceleration levels (values of n in FIG. 10). This shows that the value of b in Formula (8) is not changed according to the acceleration level when the degradation curve is fit by Formula (8).

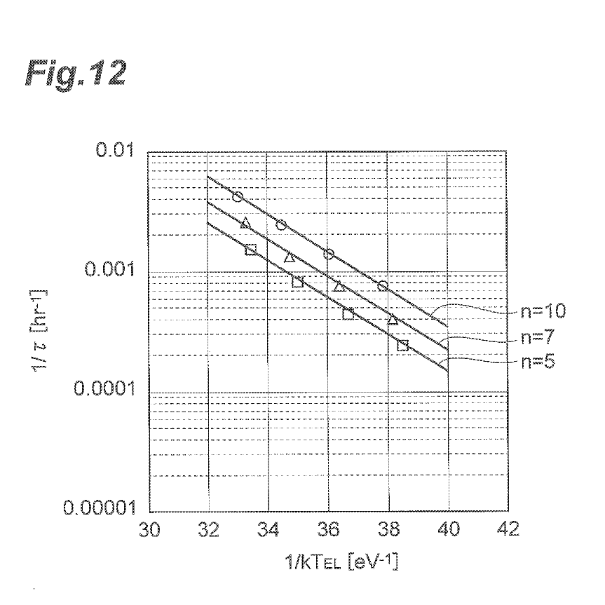

Subsequently, as in the above embodiment, in order to know the organic layer temperature T_{EL} dependence of the degradation parameter τ, an Arrhenius plot (logarithmic plot of 1/τ with respect to 1/kT_{EL}) is performed as shown in FIG. 12. As can be seen from FIG. 12, 1/k shows a substantially constant slope with respect to 1/kτ_{EL} in a single logarithmic plot, regardless of the magnitude of the current density applied to the organic EL element.

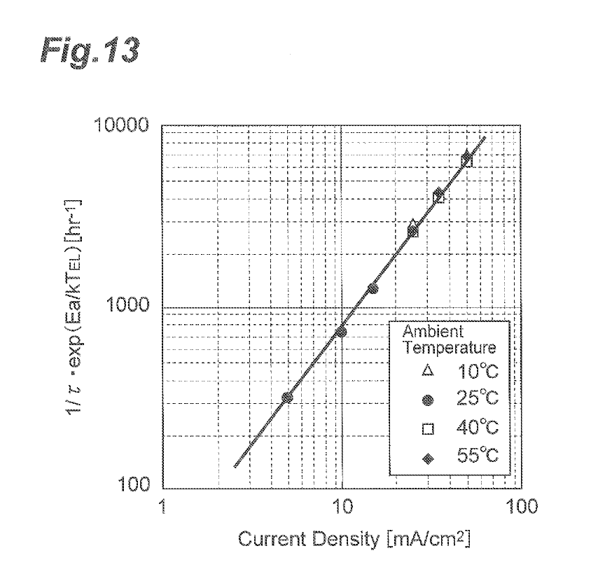

On the other hand, in order to exclude the organic layer temperature T_{EL} dependence of the degradation parameter τ and know the dependence of the degradation parameter τ with respect to the current density applied to the organic EL element, a logarithmic plot of 1/τ·exp (Ea/kT_{EL}) is performed with respect to the current density as shown in FIG. 13. As can be seen from FIG. 13, 1/τ·exp (Ea/T_{EL}) shows a substantially con slope with respect to the current density in the logarithmic plot.

From FIGS. 12 and 13, it can be seen that τ is expressed by the following Formula (10). A represents a positive number.

$$\begin{matrix}[ Math . 16 ] & \\ \frac{1}{τ} = A \cdot {J}^{β} \cdot exp ( - \frac{Ea}{{kT}_{EL}} ) & ( 10 )\end{matrix}$$

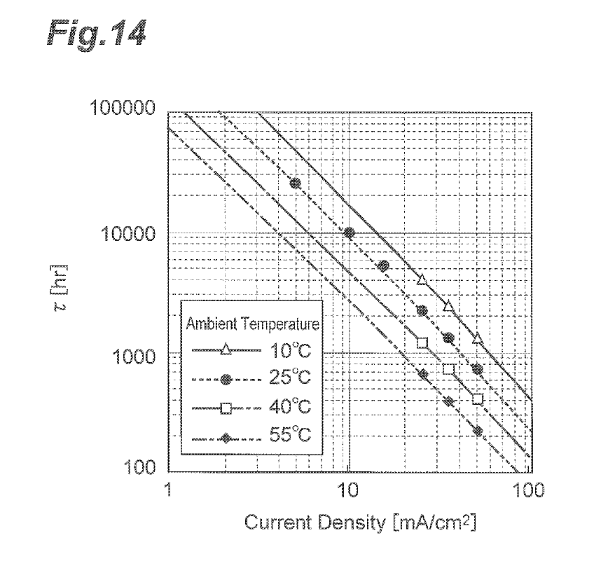

FIG. 14 shows the result obtained by plotting the degradation parameter t acquired from the lifetime test at each ambient temperature with respect to the current density. In addition, in FIG. 14, a relationship between the current density and the degradation parameter τ, which is calculated by Formula (10) at each ambient temperature, is indicated by a solid line, a dashed line, and the like. As is obvious from FIG. 14, it can be seen that the relationship between the applied current density and the degradation parameter τ, which is acquired by Formula (10) including the organic layer temperature T_{EL}, well reproduces the current density dependence of the degradation parameter τ acquired from the lifetime test.

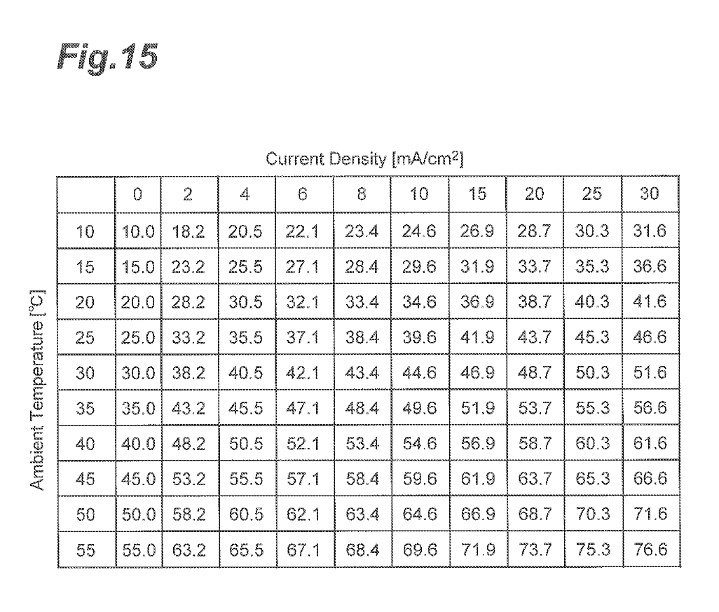

The lifetime estimation unit 2 of the lifetime estimation device 1 may include a table for deriving the temperature rise value from the applied current density and/or the ambient temperature. The table for deriving the temperature rise value from the applied current density and/or the ambient temperature is, for example, a conversion table for converting the applied current density and the ambient temperature into the organic layer temperature (temperature rise value) as shown in FIG. 15.

The temperature acquisition unit 3 of the lifetime estimation device 1 may be configured by, for example, a temperature acquisition system. In this case, as the above-described temperature rise value, a temperature rise value acquired by the temperature acquisition system can be used. In the following, an example of the temperature acquisition system will be described.

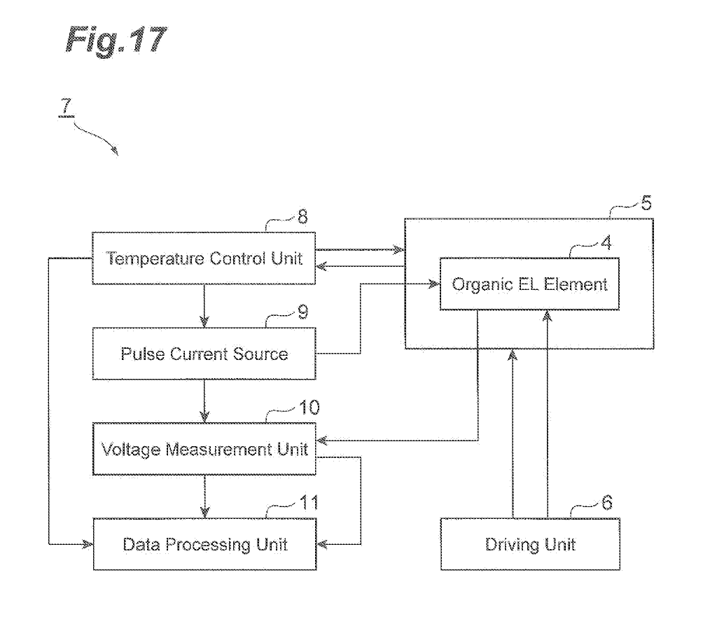

FIG. 17 is a diagram showing elements of the temperature acquisition system according to the present embodiment. As shown in FIG. 17, the temperature acquisition system 7 includes a temperature control unit 8, a pulse current source 9, a voltage measurement unit 10, a data processing unit 11, an installation unit 5 that installs an organic EL element 4, and a driving unit 6 that drives the organic EL element 4. The installation unit 5 and the driving unit 6 may be provided as a part of the temperature acquisition system, but may be provided at the outside separately from the temperature acquisition system.

The temperature control unit 8 controls the atmosphere temperature of the organic EL element 4 (for example, a temperature of a thermostatic bath (installation unit 5)). The pulse current source 9 applies a pulse current to the organic EL element 4. The voltage measurement unit 10 measures a voltage between a pair of electrodes constituting the organic EL element 4 (hereinafter, simply referred to as an “inter-electrode voltage”) when the pulse current is applied to the organic EL element 4 by the pulse current source 9. The data processing unit 11 acquires data about the correlation between the temperature of the organic layer and the inter-electrode voltage measured by the voltage measurement unit 10.

In the temperature acquisition system 7, the first to fifth steps are performed as follows. In the first step, first, the temperature control unit 8 changes the atmosphere temperature of the organic EL element 4, for example, at intervals of 5 to 20° C. between −40° C. and 80° C. In this case, the temperature control unit 8 receives, for example, from the installation unit 5, data about whether or not the temperature of the organic EL element 4 is stabilized at each atmosphere temperature of the organic EL element 4. Specifically, the installation unit 5 measures a temperature of a substrate surface of the organic EL element 4 by using, for example, a thermocouple, and transmits, to the temperature control unit 8, a signal indicating that the temperature of the organic EL element 4 has been stabilized, when the temperature is constantly maintained for ten minutes. As described above, since the measurement of the inter-electrode voltage, which is to be described below, is performed after the temperature of the organic EL element 4 has been stabilized, the correlation between the inter-electrode voltage and the atmosphere temperature can be regarded as the correlation between the inter-electrode voltage and the temperature of the organic layer.

Subsequently, the temperature control unit 8 transmits, to the pulse current source 9, the effect that the signal indicating that the temperature of the organic EL element 4 has been stabilized is received from the installation unit 5, and transmits the temperature of the organic layer of the organic EL element 4 to the data processing unit 11. Due to this, the pulse current source 9 applies the pulse current to the organic EL element 4 and transmits the signal of the effect to the voltage measurement unit 10.

The pulse current source 9 charges the electrostatic capacitance of the organic EL element 4 and applies, to the organic EL element 4, a pulse current having a pulse width, whose current value sufficiently rises to a desired value, from the viewpoint that accurately measures the inter-electrode voltage. From the view point that suppresses the temperature rise of the organic layer of the organic EL element 4 by the application of the pulse current, the pulse current source 9 applies, to the organic EL element 4, a pulse current having a pulse width of preferably 20 milliseconds or less, more preferably 10 milliseconds or less, and further more preferably 5 milliseconds or less.

From the viewpoint that suppresses the temperature rise of the organic layer of the organic EL element 4 by the application of the pulse current, the pulse current source 9 applies a pulse current having a set current value to the organic EL element 4. If the temperature rise of the organic layer of the organic EL element 4 can be suppressed by the application of the pulse current, the temperature dependence of the inter-electrode voltage can be accurately acquired. As a result, the temperature of the organic layer of the organic EL element 4 can be more accurately measured.

Specifically, the pulse current source 9 applies the pulse current to the organic EL element 4 such that the temperature rise of the organic layer of the organic EL element by the application of the pulse current is sufficiently smaller than the temperature rise of the organic layer by the current applied in the lifetime test or the like. Specifically, the temperature rise value of the organic layer by the current value of the pulse current is preferably 1° C. or less and more preferably 0.1° C. The temperature rise value of the organic layer of the organic EL element 4 can be calculated based on parameters such as, for example, an area to which the pulse current is applied in the organic EL element 4, a thickness of the organic layer, a specific heat of the organic layer, a density of the organic layer, an amount of heat by the current pulse, or a heat capacity of the organic EL element 4 (if necessary, a value of each parameter is assumed).

The voltage measurement unit 10 measures the inter-electrode voltage of the organic EL element 4 in synchronization with a timing at which the pulse current source 9 applies the pulse current to the organic EL element 4, and transmits the measured inter-electrode voltage to the data processing unit 11. The data processing unit 11 stores the temperature of the organic layer of the organic EL element 4 received from the temperature control unit 8 and the inter-electrode voltage at the temperature of the organic layer received from the data processing unit 11 in association with each other.

In the first step, the temperature control unit 8, the pulse current source 9, the voltage measurement unit 10, and the data processing unit 11 repeat the above operation to measure the inter-electrode voltage at each temperature of the organic layer of the organic EL element 4. In this way, the data processing unit 11 acquires data about the correlation between the inter-electrode voltage and the temperature of the organic layer.

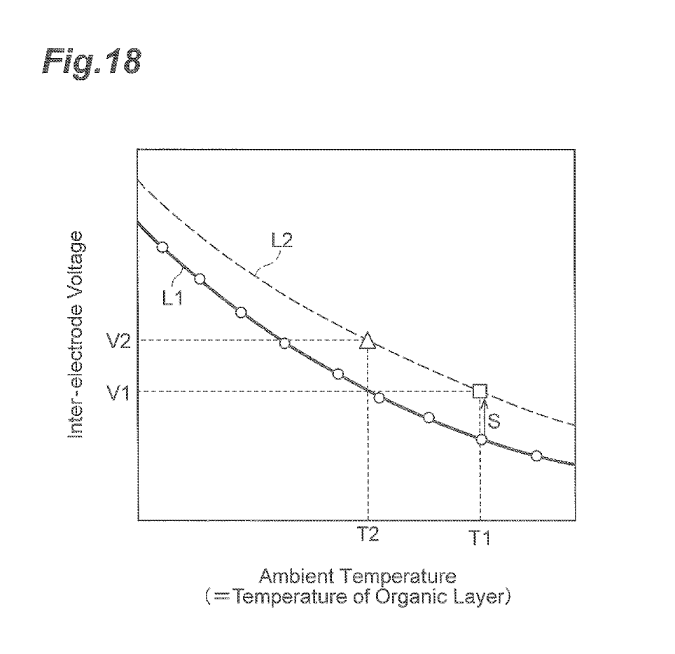

When the inter-electrode voltage at each temperature of the organic layer measured as described above is plotted, for example, a plot indicated by circular marks in FIG. 18 is acquired. Based on the plot, an initial calibration curve L1 (initial data) indicating the correlation between the inter-electrode voltage and the temperature of the organic layer is acquired.

A history of the organic EL element 4, which is provided in the first step, is not limited, but it is desirable that the history is stabilized by aging. In addition, a history may have already been driven for a predetermined time.

Subsequent to the first step, the second step is performed. The second step corresponds to, for example, a step of performing a lifetime test. In the second step, the driving unit 6 drives the organic EL element 4 by applying a predetermined DC current to the organic EL element 4 and then stops the driving. The driving condition of the organic EL element 4 is not particularly limited, and may be a normal condition (for example, a condition that applies a DC current such that an initial luminance of the organic EL element 4 becomes 3,000 cd/m² at atmosphere temperature of 25° C.) or may be a condition that accelerates degradation (for example, a condition that applies a DC current such that an initial luminance of the organic EL element 4 becomes 30,000 cd/m² at atmosphere temperature of 55° C.).

Subsequent to the second step, the third step is performed. In the third step, first, the temperature of the organic layer is maintained at a predetermined temperature T₁ by maintaining the atmosphere temperature of the organic EL element 4 at a predetermined temperature T₁. From the viewpoint that stabilizes the correlation between the inter-electrode voltage and the temperature of the organic layer, the temperature T₁ of the organic layer of the organic EL element 4 at that time is preferably 50° C. or more. In addition, in this step, one or more steps of applying a reverse bias voltage, irradiating ultraviolet light to the element, and the like may be used. Also, the time for which the temperature of the organic layer of the organic EL element is maintained at a predetermined temperature T₁ can be, for example, 30 minutes.

Subsequently, the pulse current source 9 applies the pulse current to the organic EL element 4 and transmits the signal of the effect to the voltage measurement unit 10. Here, the pulse current applied to the organic EL element 4 by the pulse current source 9 is a current having the same pulse width and current value as the pulse current applied in the first step.

The voltage measurement unit 10 measures the inter-electrode voltage V₁ of the organic EL element 4 in synchronization with a timing at which the pulse current source 9 applies the pulse current to the organic EL element 4, and transmits the measured inter-electrode voltage V₁ to the data processing unit 11. In the third step, only one inter-electrode voltage may be measured at one temperature, or a plurality of inter-electrode voltages may be measured at a plurality of different temperatures.

Subsequent to the third step, the fourth step is performed. In the fourth step, first, the data processing unit 11 compares the temperature T₁ of the organic layer of the organic EL element 4 received from the temperature control unit 8 and the inter-electrode voltage V₁ received from the voltage measurement unit 10 with the initial calibration curve L1 acquired in the first step, and acquires a corrected calibration curve L2 (correction data) by shifting the initial calibration curve L1 with respect to the shift amount from the initial calibration curve L1 of the temperature T₁ and the inter-electrode voltage V₁. Specifically, for example, as shown in FIG. 18, the corrected calibration curve L2 is acquired by shifting the entire initial calibration curve L1 by the shift amount S with respect to the initial calibration curve L1 of the plot (square mark in FIG. 18) of the inter-electrode voltage V₁ at the temperature T₁ of the organic layer.

In a case where a plurality of inter-electrode voltages V₁ is measured in the third step, the data processing unit 11 can acquire the corrected calibration curve L2 in the fourth step, based on the measured inter-electrode voltages V₁ at a plurality of temperatures T₁ of the organic layer. In this case, the data processing unit 11 can acquire the corrected calibration curve L2 with higher accuracy.

In the fifth step, in order to measure the temperature of the organic layer of the organic EL element 4, the pulse current source 9 applies the pulse current to the organic EL element 4, and the voltage measurement unit 10 measures the inter-electrode voltage V₂ at that time. Here, the pulse current applied to the organic EL element 4 by the pulse current source 9 is a current having the same pulse width and current value as the pulse current applied in the first step. The voltage measurement unit 10 transmits the measured inter-electrode voltage V₂ to the data processing unit 11.

The data processing unit 11 acquires the temperature T₂ of the organic layer of the organic EL element 4 corresponding to the inter-electrode voltage V₂ based on the corrected calibration curve L2. Specifically, for example, as shown in FIG. 18, the temperature T₂ of the organic layer of the organic EL element 4 corresponding to the inter-electrode voltage V₂ (triangular marks in FIG. 18) on the corrected calibration curve L2 acquired in the fourth step is acquired. The fifth step is appropriately performed according to a timing at which the temperature of the organic layer is intended to be measured after the second step.

As described above, in the temperature acquisition system 7, the voltage measurement unit 10 measures the inter-electrode voltage V₁ when the pulse current is applied to the driven organic EL element, and the data processing unit 11 acquires the correction data by correcting the initial data about the correlation between the previously measured temperature and voltage of the organic layer based on the temperature T₁ and the voltage V₁ of the organic layer. Therefore, the temperature of the organic EL element 4 is measured based on the correlation between the temperature and the inter-electrode voltage of the organic layer in the degraded organic EL element 4. Therefore, the temperature of the organic layer can also be measured with high accuracy with respect to the organic EL element 4 degraded along with the driving.

In the above embodiment, before the first step, a step (preliminarily driving step) may be performed to drive the organic EL element 4 at the same applied current value as the applied current value in the second step. In the preliminarily driving step, the driving unit 6 drives the organic EL element 4 at the same applied current value as the applied current value in the second step, for example, for 1 to 60 minutes. Therefore, the temperature of the organic layer can also be measured with high accuracy with respect to the organic EL element 4 in which the correlation between the inter-electrode voltage and the temperature of the organic layer is changed by the current application itself.

More specifically, according to the configuration of the organic EL element, even when the current is applied for a short time, the calibration curve indicating the correlation between the inter-electrode voltage and the temperature of the organic layer may be shifted to a high voltage side or a low voltage side, regardless of the presence or absence of the current application for a long time in the lifetime test or the like. The shift amount may be changed depending on the applied current value for a relatively short time. Therefore, with respect to such an organic EL element, it is preferable to acquire the initial calibration curve considering the current application itself. The preliminarily driving step can be omitted with respect to the organic EL element in which the shift of the calibration curve is small by the current application for a short time.

Also, the first step may include the preliminarily driving step. That is, the first step may include a step of driving the organic EL element at the same applied current value as the applied current value in the second step after the organic EL element is maintained for a predetermined time and before the pulse current is applied to the organic EL element, at all or part of the atmosphere temperatures of the plurality of atmosphere temperatures. In this case, the initial calibration curve considering the applied current value and the temperature of the organic layer can be acquired with respect to the organic EL element in which the shift amount of the calibration curve is dependent on the applied current value as well as the current application for a short time as described above.

Specifically, for example, in the first step,

(i) At all of the plurality of atmosphere temperatures, a step (step 1a) may be performed to maintain the organic EL element for a predetermined time under each atmosphere temperature and acquire the initial data about the correlation between the temperature of the organic layer and the voltage by measuring the inter-electrode voltage when the pulse current is applied to the organic EL element,

(ii) At all of the plurality of atmosphere temperatures, a step (step 1b) may be performed to drive the organic EL element at the same applied current value as the applied current value in the second step after maintaining the organic EL element for a predetermined time under each atmosphere temperature, and further after that, acquire the initial data about the correlation between the temperature of the organic layer and the voltage by measuring the inter-electrode voltage when the pulse current is applied to the organic EL element, and

(iii) The step 1a may be performed at some of the plurality of atmosphere temperatures, and the step 1b may be performed at some other of the plurality of atmosphere temperatures.

Also, the preliminarily driving step may be performed, for example, after the second step or the third step, and then, the initial data may be acquired again. Even in this case, similarly, the temperature of the organic layer can also be measured with high accuracy with respect to the organic EL element 4 in which the correlation between the inter-electrode voltage and the temperature of the organic layer is changed by the current application itself.

Also, in the present embodiment, the quality of the produced organic EL element can be accurately determined by using the above-described method for estimating the organic EL element in the manufacture of the organic EL element. That is, a method for manufacturing an organic EL element according to the present embodiment includes: a step of acquiring the organic EL element by disposing an organic layer between a pair of electrodes; a step of estimating the lifetime of the acquired organic EL element by using the above-described method for estimating the lifetime of the organic EL element; and a step of comparing the estimated lifetime with a reference value of the lifetime and determining whether the organic EL element has the acceptable quality or not.

A light-emitting device according to the present embodiment has, for example, the same configuration as the lifetime estimation device of the organic EL element shown in FIG. 1. That is, the light-emitting device includes an organic EL element, a lifetime estimation unit that estimates the lifetime of the organic EL device by using the above-described method for estimating the lifetime of the organic EL element, and a temperature acquisition unit that acquires a temperature rise value. As such a light-emitting device, a display device and a lighting device are exemplified.

The lifetime estimation unit may include a table that derives the temperature rise value from an applied current density and/or an ambient temperature. The temperature acquisition unit may be configured by, a temperature acquisition system shown in FIG. 17. The light-emitting device may further include a lifetime determination unit that determines the lifetime of the organic EL element by comparing the estimated lifetime and a reference value of the lifetime. The light-emitting device may further include a control unit that controls a driving condition of the organic EL element based on the temperature of the organic EL element acquired by the temperature acquisition unit or the lifetime of the organic EL element acquired by the lifetime estimation unit. In this case, the driving condition of the organic EL element can be controlled to a suitable condition according to the measured temperature and the lifetime of the organic EL element.

### Example

### Example 1

First, the organic EL element was manufactured. Specifically, a hole injection layer and a hole transport layer were formed by a vacuum deposition process on a glass substrate on which ITO patterns were formed, and furthermore, an emission layer was formed by a vacuum deposition process using co-evaporation. Continuously, a hole blocking layer, an electron transport layer, and an electron injection layer were formed by a vacuum deposition process in a similar manner, and finally, a cathode made of aluminum was formed. Such a manufactured organic EL layer was sealed in a glove box that was held in an inert gas so as not to be exposed to atmosphere, thereby completing the organic EL element. A material used in each layer and a film thickness of each layer are shown in Table 1.

TABLE 1

| Layer | | | |
|---|---|---|---|
| configuration | Material | Thickness | |
| Cathode | aluminum (Al) | 150 | nm |
| Electron | lithium fluoride (LiF) | 1.6 | nm |
| injection layer | | | |
| Electron | tris(8-quinolinolato)aluminum (Alq₃) | 30 | nm |
| transport layer | | | |
| Hole blocking | bis(2-methyl-8-quinolinolato)-4- | 10 | nm |
| layer | (phenylphenolato)aluminum (BAlq) | | |
| Emission layer | N,N′-dicarbazole-4,4′-biphenyl (CBP): | 30 | nm |
| | tris(2-phenylpyridinato)iridium (III) | | |
| | (Ir(ppy)₃) = 94:6 | | |
| Hole transport | N,N′-bis(1-naphthyl)-N,N′-bis(phenyl)- | 20 | nm |
| layer | benzidine (α~NPD) | | |
| Hole injection | 1,4,5,8,9,12-hexaazatriphenylene- | 60 | nm |
| layer | hexacarbonitrile (HAT-CN) | | |
| Anode | indium tin oxide (ITO) | 150 | nm |
| Substrate | glass | 0.7 | mm |

The manufactured organic EL element was disposed in a thermostatic bath, and a lifetime test was performed by applying a constant current to the organic EL element and measuring a degradation in the luminance of the organic EL element. The applied current density was J₀×n (J₁, J₂, . . . J₇), which was n times a current density J₀ at which an initial luminance of the organic EL element was 1,800 cd/m². A correspondence of the current densities J₁, J₂, . . . J₇ and n is as follows. J₁: n=0.5, J₂: n=1, J₃: n=2, J₄: n=3, J₅: n=5, J₆: n=7, J₇: n=10

Also, the temperature of the thermostatic bath (ambient temperature of the organic EL element) was 10° C., 25° C., 40° C., and 55° C. Table 2 shows a condition of an applied current density performed in each condition of the temperature of the thermostatic bath.

TABLE 2

| Temperature of | |
|---|---|
| Thermostatic Bath (° C.) | Applied Current Density |
| 10 | J₂, J₅, J₇ |
| 25 | J₁, J₂, J₃, J₄, J₅, J₆, J₇ |
| 40 | J₂, J₃, J₄, J₅, J₆, J₇ |
| 55 | J₂, J₃, J₄, J₅, J₆, J₇ |

As a result of the lifetime test, for example, when the lifetime test was performed in the condition that the temperature of the thermostatic bath was 25° C. and the applied current density was J₂, the degradation in the luminance of the organic EL element became the degradation curve C shown in FIG. 3. The vertical axis of the degradation curve C represents a ratio L(t)/L₀ of the luminance L(t) after time t with respect to the luminance L₀ at the beginning of the lifetime test. The degradation curve C could be fit with a fitting function expressed by the following Formula (5). In Formula (5), τ₁ and τ₂ represent the degradation parameters.

$$\begin{matrix}[ Math . 17 ] & \\ L ( t ) = {L}_{0} \cdot \{ λ \cdot exp ( - \frac{t}{{τ}_{1}} ) + ( 1 - λ ) \cdot exp ( - \frac{t}{{τ}_{2}} ) \} & ( 5 )\end{matrix}$$

FIG. 2 shows the degradation of the first term (a dashed line of a lower side whose intercept value is λ) and the second term (a dashed line of an upper side whose intercept value is 1−λ) in Formula (5). As is obvious from FIG. 2, the value of the first term was substantially zero after the elapse of about 100 hours. Also, FIG. 3 shows the degradation curve of the organic EL element at the ambient temperature of 25° C. and each applied current density J₁, J₂, . . . J₇. In a single logarithmic plot in FIG. 3, all the degradation curves J₁, J₂, . . . J₇ became straight lines after the elapse of about 100 hours.

In the organic EL element using the above-described lifetime test, a temperature rise value of the organic layer was measured before the lifetime test was performed. Specifically, the temperature rise value of the organic layer was calculated by measuring the following current-voltage characteristic (IV characteristic) of the organic EL layer.

<Measurement of Current-Voltage Characteristics (IV Characteristics)>

The temperature of the organic EL element was maintained at a constant temperature in a thermostatic bath, and a voltage at the time of applying a current pulse was measured by using a current pulse in which the temperature rise due to the driving was suppressed. By repeating the measurement while changing the temperature of the organic EL element (temperature of the thermostatic bath), the current-voltage characteristic dependent on the temperature was acquired as a calibration curve. Subsequently, the voltage was measured by promptly applying the same current pulse as described above from the state in which the organic EL element was actually driven to emit light. By comparing the voltage at the time of the driving with the calibration curve, the temperature rise value of the organic layer at the time of the driving was estimated.

When the organic layer temperature T_{EL} estimated using the temperature rise value of the organic layer calculated from the IV characteristic was plotted with respect to the current density applied to the organic EL element, the plot shown in FIG. 4 was obtained. FIG. 4 shows the curve (dashed line) approximated based on these data.

In order to know the organic layer temperature T_{EL} dependence of the degradation parameter τ₂ by using the organic layer temperature T_{EL} at each acquired condition, an Arrhenius plot (logarithmic plot of 1/τ₂ with respect to 1/kT_{EL}) was performed as shown in FIG. 5. k represents a Boltzmann constant. As can be seen from FIG. 5, 1/τ₂ shown a substantially constant slope of 0.42±0.04 eV with respect to 1/kT_{EL} in a logarithmic plot, regardless of the magnitude of the current density applied to the organic EL element.

On the other hand, in order to exclude the organic layer temperature T_{EL} dependence of the degradation parameter τ₂ and know the dependence of the degradation parameter τ₂ with respect to the current density J applied to the organic EL element, a logarithmic plot of 1/τ·exp (Ea/kT_{EL}) was performed with respect to the current density J as shown in FIG. 6. As can be seen from FIG. 6, 1/τ₂·exp (Ea/kT_{EL}) shown a substantially constant slope of 1.16±0.10 with respect to the current density J in the logarithmic plot.

From FIGS. 5 and 6, it can be seen that τ₂ was expressed by the following Formula (6). A represents a positive number. Also, in the present Example, β was 1.16 and Ea was 0.42.

$$\begin{matrix}[ Math . 18 ] & \\ \frac{1}{{τ}_{2}} = A \cdot {J}^{β} \cdot exp ( - \frac{Ea}{{kT}_{EL}} ) & ( 6 )\end{matrix}$$

FIG. 7 shows the result obtained by plotting the degradation parameter τ₂ acquired from the lifetime test at each temperature of the thermostatic bath with respect to the current density. In addition, in FIG. 7, a relationship between the current density and the degradation parameter τ₂, which is calculated by Formula (2) at each ambient temperature, is indicated by a solid line, a dashed line, and the like. As is obvious from FIG. 7, it can be seen that the relationship between the applied current density and the degradation parameter τ₂, which was acquired by Formula (6) including the organic layer temperature T_{EL}, well reproduced the current density dependence of the degradation parameter τ₂ acquired from the lifetime test.

From the above, it was found that the fitting function of the degradation data of the organic EL element according to the present Example could be the following Formula (5), and τ₂ in Formula (5) could be the following Formula (6).

$$\begin{matrix}[ Math . 19 ] & \\ L ( t ) = {L}_{0} \cdot \{ λ \cdot exp ( - \frac{t}{{τ}_{1}} ) + ( 1 - λ ) \cdot exp ( - \frac{t}{{τ}_{2}} ) \} & ( 5 ) \\ [ Math . 20 ] & \\ \frac{1}{{τ}_{2}} = A \cdot {J}^{β} \cdot exp ( - \frac{Ea}{{kT}_{EL}} ) & ( 6 )\end{matrix}$$

### Comparative Example

Regarding the result of the lifetime test of the organic EL element performed in the Example, the relationship of the degradation parameter τ₂ corresponding to the current density was calculated by using the conventional method for estimating the lifetime of the organic EL element. Specifically, in the conventional method for estimating the lifetime of the organic EL element, the degradation parameter τ₂ (n=10) was calculated based on the result of the lifetime test in the acceleration condition (for example, J=J₇ (n=10)), and then, the degradation parameter τ₂ (n=1) was calculated in the standard condition (J=J₂ (n=1)) by using the lifetime estimation formula assuming that the degradation parameter τ₂ was proportional to power of the current density. That is, in the conventional method for estimating the lifetime of the organic EL element, the lifetime estimation formula expressed by the following Formula (11) was used.

$$\begin{matrix}[ Math . 21 ] & \\ {τ}_{2} ( n = 1 ) = {τ}_{2} ( n = 10 ) \cdot {( \frac{{J}_{7}}{{J}_{2}} )}^{- {S}_{H}} & ( 11 )\end{matrix}$$

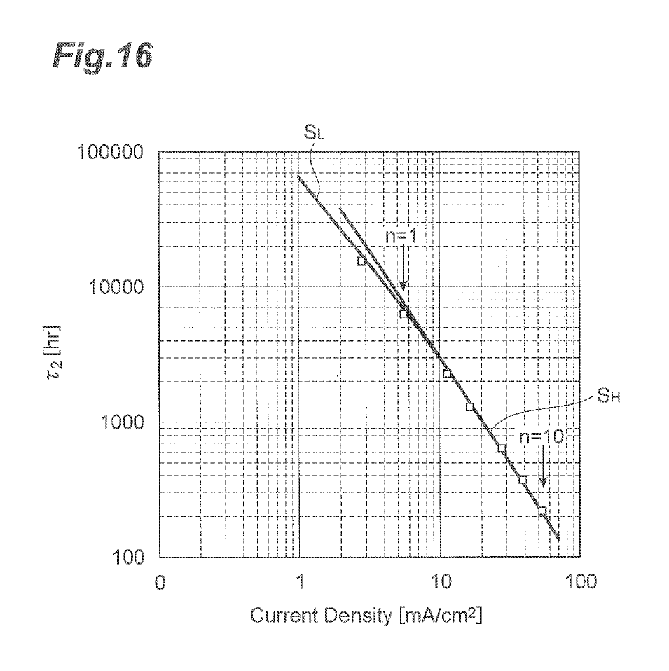

FIG. 16 shows the relationship of the degradation parameter τ₂ with respect to the current density calculated by using the conventional method for estimating the lifetime of the organic EL element. In Formula (11), S_{H} represents the slope of the degradation parameter τ₂ corresponding to the current density around J=J₇ (n=10) in FIG. 16. As can be seen from FIG. 16, in the case of using the conventional lifetime estimating method, the slope S_{H} of the degradation parameter τ₂ corresponding to the current density around the acceleration condition (for example, condition of n=10) is greatly different from the slope S_{L} of the degradation parameter τ₂ corresponding to the current density around the standard condition (for example, condition of n=1). Therefore, when the degradation parameter τ₂ in the standard condition was calculated from the degradation parameter τ₂ calculated in the acceleration condition as in Formula (11), large error occurred in the degradation parameter τ₂ in the standard condition. That is, in the conventional method for estimating the lifetime of the organic EL element, the lifetime may not be accurately estimated. In particular, in a case where the current density applied to the organic EL element is large, it may be difficult to accurately estimate the lifetime.

### Example 2

With respect to the organic EL element manufactured in the same manner as Example 1, the lifetime test was performed by measuring the degradation in the luminance in the same manner as Example 1. An applied current density was n times a current density of 5 mA/cm² (n=1, 2, 3, 5, 7, 10).

As a result of the lifetime test, the degradation in the luminance of the organic EL element at each current density became the degradation curve shown in FIG. 10. The degradation curve could be fit with a fitting function expressed by the following Formula (12). In Formula (12), b, γ, τ, and τ′ represent the degradation parameters. In the present Example, b was 0.7±0.05.

$$\begin{matrix}[ Math . 22 ] & \\ L ( t ) = {L}_{0} \cdot [ γ \cdot exp \{ - ( \frac{t}{{τ}^{′}} ) \} + ( 1 - γ ) \cdot exp \{ - {( \frac{t}{τ} )}^{b} \} ] & ( 12 )\end{matrix}$$

Then, when the elapsed time (a horizontal axis in FIG. 10) was normalized, a degradation curve as shown in FIG. 11 was acquired. The normalization of the elapsed time was performed by dividing the elapsed time by a time being a constant decay rate (for example, L(t)/L(0)=0.7, etc.). As is obvious from FIG. 11, the degradation curves almost overlapped one other with respect to the normalized elapsed time in all acceleration levels (values of n in FIG. 10). This shows that the value of b in Formula (12) is not changed according to the acceleration level when the degradation curve is fit by Formula (12).

Subsequently, as in Example 1, in order to know the organic layer temperature T_{EL} dependence of the degradation parameter t, an Arrhenius plot (logarithmic plot of 1/τ with respect to 1/kT_{EL}) was performed as shown in FIG. 12. As can be seen from FIG. 12, 1/τ shown a substantially constant slope with respect to 1/kT_{EL} in a logarithmic plot, regardless of the magnitude of the current density applied to the organic EL element.

On the other hand, in order to exclude the organic layer temperature T_{EL} dependence of the degradation parameter τ and know the dependence of the degradation parameter τ with respect to the current density applied to the organic EL element, a logarithmic plot of 1/τ·exp (Ea/kT_{EL}) was performed with respect to the current density as shown in FIG. 13. As can be seen from FIG. 13, 1/τ·exp (Ea/kT_{EL}) shown a substantially con slope with respect to the current density in the logarithmic plot.

From FIGS. 12 and 13, it can be seen that T was expressed by the following Formula (10). A represents a positive number. In the present Example, β was 1.30±0.10 and Ea was 0.36±0.02.

$$\begin{matrix}[ Math . 23 ] & \\ \frac{1}{τ} = A \cdot {J}^{β} \cdot exp ( - \frac{Ea}{{kT}_{EL}} ) & ( 10 )\end{matrix}$$

FIG. 14 shows the result obtained by plotting the degradation parameter τ acquired from the lifetime test at each temperature of the thermostatic bath with respect to the current density. In addition, in FIG. 14, a relationship between the current density and the degradation parameter τ, which is calculated by Formula (12) at each ambient temperature, is indicated by a solid line, a dashed line, and the like. As is obvious from FIG. 14, it can be seen that the relationship between the applied current density and the degradation parameter τ, which was acquired by Formula (10) including the organic layer temperature T_{EL}, well reproduced the current density dependence of the degradation parameter τ acquired from the lifetime test.

Furthermore, the result obtained by estimating the lifetime of the organic EL element (time until the luminance became 70% of the initial luminance) from the fitting function was 4,401 hours, and was well matched with 4,750 that was the actual value of the lifetime of the organic EL element.

### Example 3

Subsequently, an Example of a method for acquiring a temperature of an organic EL element by using the temperature acquisition system shown in FIG. 17 is presented.

First, the organic EL element was manufactured. Specifically, a hole injection layer and a hole transport layer were formed by a vacuum deposition process on a glass substrate on which ITO patterns were formed, and furthermore, an emission layer was formed by a vacuum deposition process using co-evaporation. Continuously, a hole blocking layer, an electron transport layer, and an electron injection layer were formed by a vacuum deposition process in a similar manner, and finally, a cathode made of aluminum was formed. Such a manufactured organic EL layer was sealed in a glove box that was held in an inert gas so as not to be exposed to atmosphere, thereby completing the organic EL element. An emission area of the acquired organic EL element was 2 mm×2 mm. A material used in each layer and a film thickness of each layer are shown in Table 3.

TABLE 3

| Layer | | | |
|---|---|---|---|
| configuration | Material | Thickness | |
| Cathode | aluminum (Al) | 150 | nm |
| Electron | lithium fluoride (LiF) | 1.6 | nm |
| injection layer | | | |
| Electron | tris(8-quinolinolato)aluminum (Alq₃) | 30 | nm |
| transport layer | | | |
| Hole blocking | bis(2-methyl-8-quinolinolato)-4- | 10 | nm |
| layer | (phenylphenolato)aluminum (BAlq) | | |
| Emission layer | N,N′-dicarbazole-4,4′-biphenyl (CBP): | 30 | nm |
| | tris(2-phenylpyridinato)iridium (III) | | |
| | (Ir(ppy)₃) = 94:6 | | |
| Hole transport | N,N′-bis(1-naphthyl)-N,N′-bis(phenyl)- | 20 | nm |
| layer | benzidine (α-NPD) | | |
| Hole injection | 1,4,5,8,9,12-hexaazatriphenylene- | 60 | nm |
| layer | hexacarbonitrile (HAT-CN) | | |
| Anode | indium tin oxide (ITO) | 150 | nm |
| Substrate | glass | 0.7 | mm |

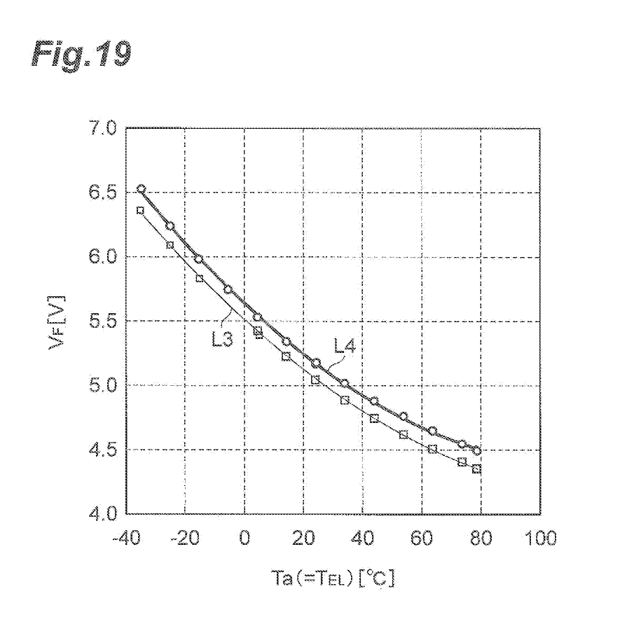

The atmosphere temperature Ta (temperature T_{EL} of the organic layer) was changed between −35° C. to 80° C. with respect to the acquired organic EL element, and the inter-electrode voltage V_{F} was measured by applying the pulse current to the organic EL element at each atmosphere temperature Ta. A pulse width of the pulse current was 20 ms, and a current value was 2 μA. A temperature rise of the organic layer of the organic EL element due to the application of the pulse current was estimated as about 0.7° C. at maximum (it was assumed that the organic layer was 100 nm, the specific heat was 1,000 J/kg·K, the density was 1 g/cm², and a heat was insulated, and the amount of heat generation was calculated as 2.8×10⁻⁷ J/pulse and the heat capacity of the element was calculated as 4.0×10⁻⁷ J/K). The measurement of the inter-electrode voltage was performed by measuring the temperature of the substrate surface of the organic EL element by using a thermocouple at each atmosphere temperature Ta while being held until the temperature was constantly maintained for ten minutes. Due to the above measurement, the initial calibration curve L3 shown in FIG. 19 was acquired.

Subsequently, the organic EL element was driven for 12 hours in the condition that the atmosphere temperature was 25° C. and the applied current was 2 mA. The result of applying the pulse current having a pulse width of 20 ms and a current value of 2 μA to the driven organic EL element and measuring the inter-electrode voltage V_{A} was 5.11 V. After that, in the same manner as the above, the inter-electrode voltage V_{F} at the time of applying the pulse current at each atmosphere temperature Ta was measured. Due to this, the corrected calibration curve L4 shown in FIG. 19 was acquired. The corrected calibration curve L4 was shifted to a high voltage side by only 0.14 V with respect to the initial calibration curve L3. The result of estimating the organic layer temperature at the applied current of 2 mA by using the calibration curve was 41° C.

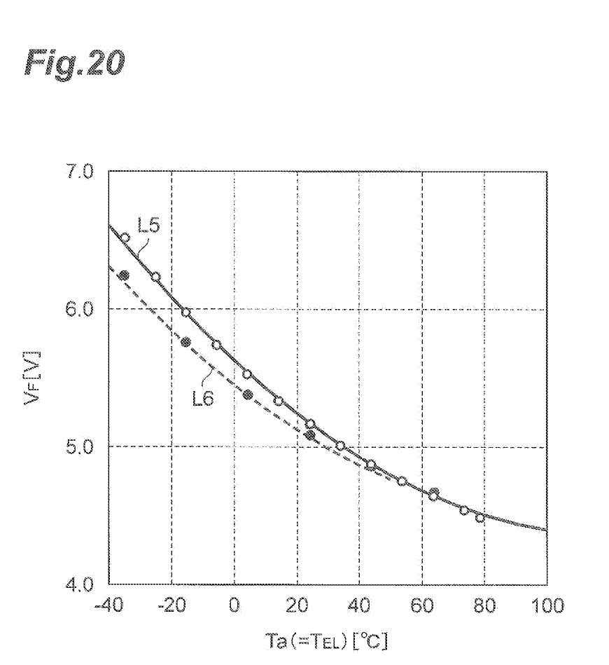

Also, in order to check the influence by the current application itself, after the same initial calibration curve L5 as the above was acquired, the inter-electrode voltage V_{F} was measured after the elapse of ten minutes from the 30-minute application of a 2-mA DC current to the organic EL element at each atmosphere temperature Ta. As shown in FIG. 20, a calibration curve L6 based on the inter-electrode voltage measured after the current application was shifted to a low voltage side with respect to the initial calibration curve L5.

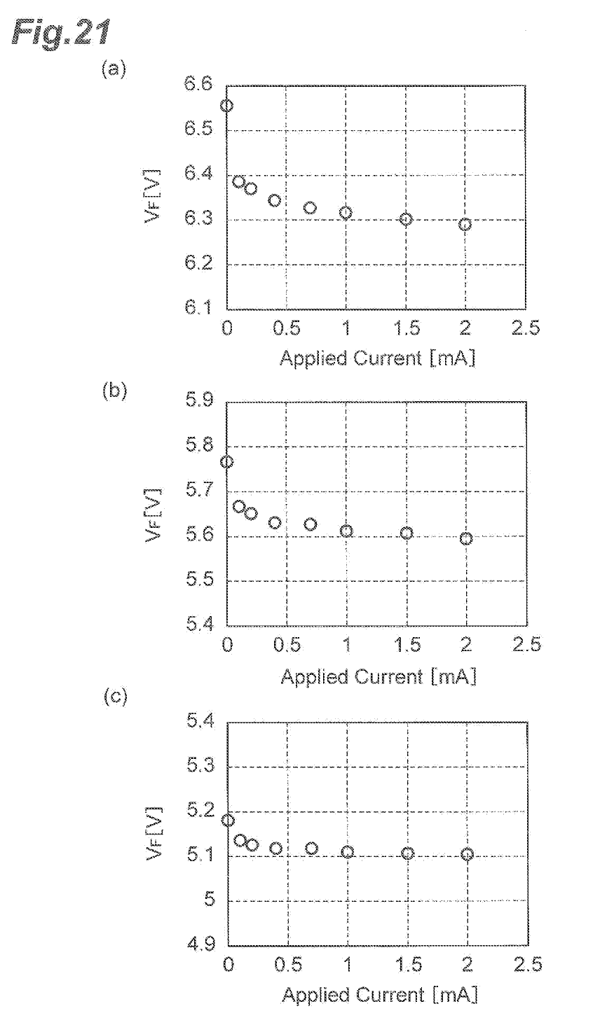

FIG. 21 includes graphs showing the relationship between the inter-electrode voltage, the applied current value, and the atmosphere temperature. Each of(a), (b), and (c) in FIG. 21 shows the inter-electrode voltages V_{F} measured after the current is applied to the organic EL element at each applied current value at the atmosphere temperatures of −35° C., −5° C., and 25° C., respectively. As is obvious from FIG. 21, in the case of the organic EL element used in the present Example, the shift amount of the inter-electrode voltage V_{F} due to the current application itself was dependent on the applied current value and the atmosphere temperature.

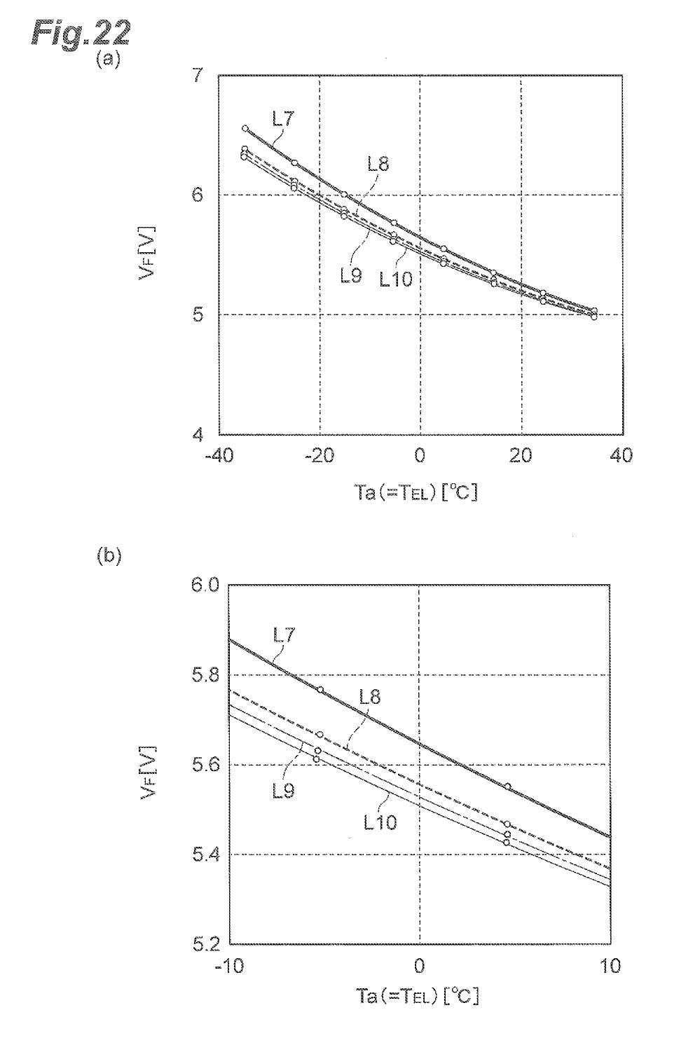

FIG. 22 includes graphs showing the relationship between the applied current value and the change in the calibration curve. (b) in FIG. 22 is an enlarged view of(a) in FIG. 22. FIG. 22 shows the calibration curves in a case (L7) where the current was not applied, a case (L8) where a current of 0.1 mA was applied, a case (L9) where a current of 1 mA was applied, and a case (L10) where a current of 2 mA was applied, before the acquisition of the calibration curve. In this example, in a case where the calibration curve was acquired without considering the influence due to the current application, the error of the temperature measurement of the organic EL element was about 7° C. (a difference between L7 and L10) at maximum when the element temperature was around 0° C. The result of estimating the organic layer temperature at the applied current of 1 mA and the atmosphere temperature of 25° C. by using the corrected calibration curve was 36° C.

### REFERENCE SIGNS LIST

1 . . . lifetime estimation device, 2 . . . lifetime estimation unit, 3 . . . temperature acquisition unit, 4 . . . organic EL element, 5 . . . installation unit, 6 . . . driving unit, 7 . . . temperature acquisition system, 8 . . . temperature control unit, 9 . . . pulse current source, 10 . . . voltage measurement unit, 11 . . . data processing unit.

1. A method for estimating a lifetime of an organic EL element comprising a pair of electrodes and an organic layer disposed between the pair of electrodes, the method comprising:
a data acquiring step of acquiring degradation data of characteristics of the organic EL element when a current density applied to the organic EL element and/or an atmosphere temperature of the organic EL element are/is changed;
a parameter extracting step of calculating a fitting function of the degradation data and extracting a degradation parameter characterizing a degradation in the characteristics at the applied current density and/or the atmosphere temperature from the fitting function;
an estimation formula setting step of calculating a temperature dependence of the degradation parameter based on a temperature rise value of the organic layer upon light emission at the applied current density and/or the atmosphere temperature and setting a lifetime estimation formula of the organic EL element; and
a lifetime estimating step of estimating the lifetime of the organic EL element based on the lifetime estimation formula.

2. The method for estimating a lifetime of an organic EL element according to claim 1, wherein the degradation parameter is a coefficient of a function characterizing the degradation of emission intensity being luminance, luminous flux, radiant flux, or the number of photons of the organic EL element, luminous efficiency representing luminous flux per unit input power, external quantum efficiency representing the number of photons taken out per unit current, or a driving voltage being a threshold value or a constant current in the fitting function.

3. The method for estimating a lifetime of an organic EL element according to claim 1, wherein, in the estimation formula setting step, the degradation parameter is corrected based on the temperature dependence, a dependence due to another factor of the degradation parameter is derived, and the lifetime estimation formula including a product of a term representing the temperature dependence and a term representing the dependence due to the other factors is set.

4. The method for estimating a lifetime of an organic EL element according to claim 3, wherein the other factor is the applied current density, an applied voltage, or input power, with respect to the organic EL element.

5. The method for estimating a lifetime of an organic EL element according to claim 1, wherein the temperature rise value is a temperature rise value acquired by measurement of current-voltage characteristics of the organic EL element, measurement of transient characteristics of the luminous intensity, or Raman spectroscopic measurement of the organic layer.

6. The method for estimating a lifetime of an organic EL element according to claim 1, wherein the temperature rise value is a temperature rise value acquired by a method comprising:
a first step of, at a plurality of atmosphere temperatures, maintaining the organic EL element for a predetermined time under each atmosphere temperature and acquiring initial data about a correlation between the temperature of the organic layer and the voltage by measuring a voltage between the electrodes when a pulse current is applied to the organic EL element;
a second step of driving and stopping the organic EL element;
a third step of, after the second step, maintaining the organic EL element for a predetermined time under a predetermined atmosphere temperature (T₁) and measuring a voltage (V₁) when the same pulse current as the pulse current in the first step is applied to the organic EL element;
a fourth step of correcting the initial data based on the temperature (T₁) and the voltage (V₁) acquired in the third step and acquiring correction data about the correlation between the temperature of the organic layer and the voltage; and
a fifth step of measuring a voltage (V₂) between the electrodes when the same pulse current as the pulse current in the first step is applied to the organic EL element and acquiring a temperature (T₂) corresponding to the voltage (V₂) based on the correction data.

7. The method for estimating a lifetime of an organic EL element according to claim 6, further comprising, before the first step, a step of driving the organic EL element at the same applied current value as the applied current value in the second step.

8. The method for estimating a lifetime of an organic EL element according to claim 6, wherein the first step comprises a step of driving the organic EL element at the same applied current value as the applied current value in the second step before the pulse current is applied to the organic EL element, at all or part of the atmosphere temperatures of the plurality of atmosphere temperatures.

9. The method for estimating a lifetime of an organic EL element according to claim 1, wherein, in the data acquiring step, a degradation in the temperature is measured by acquiring the temperature rise value of the organic layer along with the degradation parameter, and
in the estimation formula setting step, the lifetime estimation formula is set based on a degradation in the temperature rise value.

10. The method for estimating a lifetime of an organic EL element according to claim 1, wherein the fitting function of the degradation data is the following Formula (1), (2), or (3):
$$\begin{matrix}[ Math . 1 ] & \\ L ( t ) = {L}_{0} \cdot \sum \{ {a}_{i} \cdot exp ( - \frac{t}{{τ}^{′}} ) \} \\ where , \sum {a}_{i} = 1 ) & ( 1 ) \\ [ Math . 2 ] & \\ L ( t ) = {L}_{0} \cdot exp \{ - {( \frac{t}{τ} )}^{b} \} & ( 2 ) \\ [ Math . 3 ] & \\ L ( t ) = \frac{{L}_{0}}{{( 1 + ct )}^{d}} \\ where , 1 < d < 2 ) & ( 3 )\end{matrix}$$
[in Formulas (1), (2), and (3), L(t) represents emission intensity after time t from the beginning of a lifetime test of the organic EL element, L₀ represents emission intensity at the beginning of the lifetime test of the organic EL element, and aᵢ, b, c, d, τᵢ, and τ represent degradation parameters.]

11. The method for estimating a lifetime of an organic EL element according to claim 1, wherein the fitting function of the degradation data is the following Formula (7), (8), or (9):
$$\begin{matrix}[ Math . 4 ] & \\ L ( t ) = {L}_{0} \cdot [ γ \cdot g ( t ) + ( 1 - γ ) \cdot \sum \{ {a}_{i} \cdot exp ( - \frac{t}{{τ}_{i}} ) \} ] \\ where , \sum {a}_{i} = 1 ) & ( 7 ) \\ [ Math . 5 ] & \\ L ( t ) = {L}_{0} \cdot [ γ \cdot g ( t ) + ( 1 - γ ) \cdot exp \{ - {( \frac{t}{τ} )}^{b} \} ] & ( 8 ) \\ [ Math . 6 ] & \\ L ( t ) = {L}_{0} \cdot \{ γ \cdot g ( t ) + ( 1 - γ ) \cdot \frac{1}{{( 1 + ct )}^{d}} \} \\ where , 1 < d < 2 ) & ( 9 )\end{matrix}$$
[in Formulas (7), (8), and (9), L(t) represents emission intensity after time t from the beginning of a lifetime test of the organic EL element, L₀ represents the emission intensity at the beginning of the lifetime test of the organic EL element, aᵢ, b, c, d, τᵢ, τ, and γ represent degradation parameters, and g(t) represent a function of t corresponding to an initial degradation of the organic EL element.]

12. A lifetime estimation device of an organic EL element for estimating the lifetime of the organic EL element, the lifetime estimation device comprising:
a lifetime estimation unit estimating the lifetime of the organic EL element by using the method for estimating the lifetime of the organic EL element according to claim 1; and
a temperature acquisition unit that acquires the temperature rise value.

13. The lifetime estimation device according to claim 12, wherein the temperature acquisition unit is configured by a temperature acquisition system comprising:
a temperature control unit controlling the atmosphere temperature of the organic EL element;
a pulse current source applying a pulse current to the organic EL element;
a voltage measurement unit measuring a voltage between the pair of electrodes when the pulse current is applied to the organic EL element; and
a data processing unit processing the data about the correlation between the temperature of the organic layer and the voltage.

14. A method for manufacturing an organic EL element, the method comprising:
a step of acquiring an organic EL element by disposing an organic layer between a pair of electrodes;
a step of estimating a lifetime of the organic EL element by using the method for estimating the lifetime of the organic EL element according to claim 1; and
a step of comparing the estimated lifetime with a reference value of the lifetime and determining whether the organic EL element has the acceptable quality or not.

15. A light-emitting device comprising:
an organic EL element;
a lifetime estimation unit estimating a lifetime of the organic EL element by using the method for estimating the lifetime of the organic EL element according to claim 1; and
a temperature acquisition unit acquiring the temperature rise value.

16. The light-emitting device according to claim 15, wherein the temperature acquisition unit is configured by a temperature acquisition system comprising:
a temperature control unit controlling the atmosphere temperature of the organic EL element;
a pulse current source applying a pulse current to the organic EL element;
a voltage measurement unit measuring a voltage between the pair of electrodes when the pulse current is applied to the organic EL element; and
a data processing unit processing the data about the correlation between the temperature of the organic layer and the voltage.

17. The light-emitting device according to claim 15, further comprising a lifetime determination unit that determines the lifetime of the organic EL element by comparing the estimated lifetime and a reference value of the lifetime.
